(19) United States
(12) Patent Application Publication
(10) Pub. No.: US 2025/0130497 A1
(43) Pub. Date: Apr. 24, 2025

(54) METHOD FOR IMPROVING HARDNESS OF BAKED PRODUCT

(71) Applicant: NISSAN CHEMICAL CORPORATION, Tokyo (JP)

(72) Inventors: Hayato HATTORI, Toyama-shi (JP); Akihito IZUMI, Toyama-shi (JP)

(73) Assignee: NISSAN CHEMICAL CORPORATION, Tokyo (JP)

(21) Appl. No.: 18/835,154

(22) PCT Filed: Feb. 3, 2023
(86) PCT No.: PCT/JP2023/003611

§ 371 Date: Aug. 1, 2024

(30) Foreign Application Priority Data
Feb. 3, 2022 (JP) 2022-015726

(51) Int. Cl. G03F 7/039; C08L 101/02; G03F 7/11; H01L 21/308

(52) U.S. Cl. CPC G03F 7/0395; C08L 101/02; G03F 7/11; H01L 21/3081; H01L 21/3086; H01L 21/3088

(57) ABSTRACT

A method for improving hardness of a baked product, including baking a composition including a compound containing one or more structures of the following Formula (1) at 400° C. to 600° C. under an inert gas atmosphere to increase hardness of an obtained baked product by 10% or more compare to hardness of a baked product at 350° C. under an air atmosphere; a resist underlayer film for use in a lithography process composed of the baked product; a method of the resist underlayer film; and a method of producing a semiconductor device:

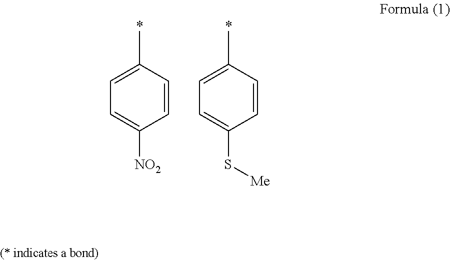

### TECHNICAL FIELD

The present invention relates to a method for improving the hardness of a baked product and a baked product having improved hardness.

### BACKGROUND ART

Polymerization of polymer resins has been widely studied, and particularly, polymers containing ring structures such as novolac have been widely used in a wide range of applications from minute applications such as photoresists to general applications such as automobile and housing members. In addition, the above polymers have high heat resistance and can be used for special applications, and thus their development is currently underway around the world. Generally, regarding monomers having a ring structure, structures such as benzene, naphthalene, anthracene, pyrene and fluorene are known, and these monomers are known to form novolacs with monomers having an aldehyde group. On the other hand, carbazole, which has a structure similar to fluorene, also exhibits similar characteristics, and it has been found that, in both monomers, a part of a benzene ring adjacent to a five-membered ring reacts and polymerizes.

On the other hand, conventionally, in production of semiconductor devices, fine processing by lithography has been performed using a photoresist composition. Fine processing is a processing method in which a thin film of a photoresist composition is formed on a substrate to be processed such as a silicon wafer, active light such as ultraviolet light is emitted thereonto through a mask pattern on which a semiconductor device pattern is drawn, developing is performed, and a substrate to be processed such as a silicon wafer is etched using the obtained photoresist pattern as a protective film. Incidentally, in recent years, as semiconductor devices have become highly integrated, the wavelength of active light used has been shortened from KrF excimer laser (248 nm) to ArF excimer laser (193 nm). Accordingly, the influence of diffused reflection and standing waves of active light from a substrate has become a major problem. Therefore, methods of providing an anti-reflective film between a photoresist and a substrate to be processed have been widely studied.

In the future, as resist patterns become finer, resolution problems and problems such as resist patterns collapsing after development will occur, and there will be a demand for thinner resists. Therefore, it is difficult to obtain a resist pattern film thickness sufficient for substrate processing, and a process in which not only the resist pattern but also the resist underlayer film formed between the resist and the semiconductor substrate to be processed can function as a mask during substrate processing has become required. Unlike conventional resist underlayer films with high etch rates (fast etching rates) as resist underlayer films for such processes, there are demands for lithography resist underlayer films having a dry etching rate selectivity close to that of the resist, lithography resist underlayer films having a dry etching rate selectivity smaller than that of the resist, lithography resist underlayer films having a dry etching rate selectivity smaller than that of the semiconductor substrate, and also lithography resist underlayer films having a low etching rate while minimizing pattern bending during etching.

Examples of polymers for the resist underlayer film include the following examples.

Resist underlayer film-forming compositions using carbazole are exemplified (refer to Patent Document 1, Patent Document 2, Patent Document 3, Patent Document 4, and Patent Document 5).

### PRIOR ART DOCUMENTS

### Patent Documents

Patent Document 1: WO2010/147155 A1
Patent Document 2: WO2012/077640 A1
Patent Document 3: WO2013/005797 A1
Patent Document 4: WO2014/092155 A1
Patent Document 5: WO2017/188263 A1

### SUMMARY OF THE INVENTION

### Problem to be Solved by the Invention

The present invention provides a method for improving the hardness of a baked product, a baked product having improved hardness obtained by the method, a resist underlayer film for use in a lithography process composed of the baked product, a method of producing the resist underlayer film and a method of producing a semiconductor device.

The present invention has been made in order to address such problems, and the inventors conducted extensive studies, and as a result, found a method for improving the hardness of a baked product through which the hardness is increased by 10% or more compared to conventional baked products.

### Means for Solving the Problem

The present invention includes the following aspects.

1. A method for improving hardness of a baked product, comprising
baking a composition including a compound containing one or more structures of the following Formula (1) at 400° C. to 600° C. under an inert gas atmosphere to increase hardness of an obtained baked product by 10% or more compared to hardness of a baked product at 350° C. under an air atmosphere.

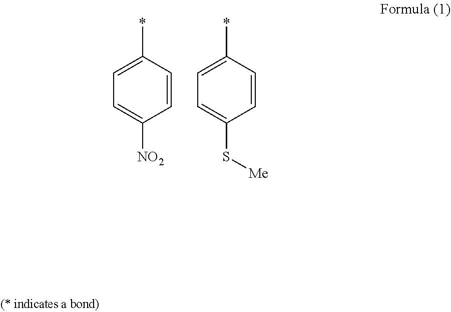

2. The method for improving hardness of a baked product according to the above 1,
wherein the compound contains a polymer structure having at least one repeating unit of the following Formula (2):

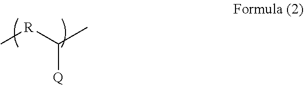

(wherein R is a divalent group having an aromatic ring, a condensed aromatic ring, or a condensed aromatic heterocycle, and Q is one of the structures of Formula (1)).
3. The method for improving hardness of a baked product according to the above 2,
wherein R is a divalent group in which hydrogen atoms on an aromatic ring having a structure of the following Formula (3), Formula (4), or Formula (5) are substituted:

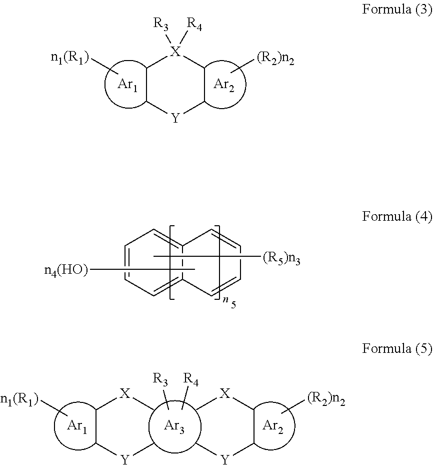

(in Formula (3), at least one of X and Y is present; X is a nitrogen atom or a carbon atom, Y is a single bond, a sulfur atom, or an oxygen atom; each of Ar₁ and Ar₂ is independently a benzene ring or a naphthalene ring which is arbitrarily substituted with R₁ or R₂, each of R₁ and R₂ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, or a combination thereof which arbitrarily contains an ether bond, a ketone bond, or an ester bond; each of n₁ and n₂ is an integer of 1 to 3 when Ar₁ and Ar₂ are benzene rings, and an integer of 1 to 5 when Ar₁ and Ar₂ are naphthalene rings; and each of R₃ and R₄ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, a phenyl group, a phenyl group substituted with a hydroxyl group, or a combination thereof which arbitrarily contains an ether bond, a ketone bond, or an ester bond; where, when X is a nitrogen atom, R₄ is absent; in Formula (4), R₅ is a C₁₋₃ alkyl group, n₃ is an integer of 0 to 4, n₄ is an integer of 1 to 4, and n₅ is any of 0, 1, and 2; and in Formula (5), Ar₁, Ar₂, R₁, R₂, R₃, R₄, n₁, and n₂ are the same as above, Ar₃ is a benzene ring or a naphthalene ring which is arbitrarily substituted with R₃ and R₄; and R₃ and R₄ are the same as above).
4. The method according to the above 2 or 3,
wherein R is a divalent group in which hydrogen atoms on an aromatic ring having any one of the following structures are substituted:

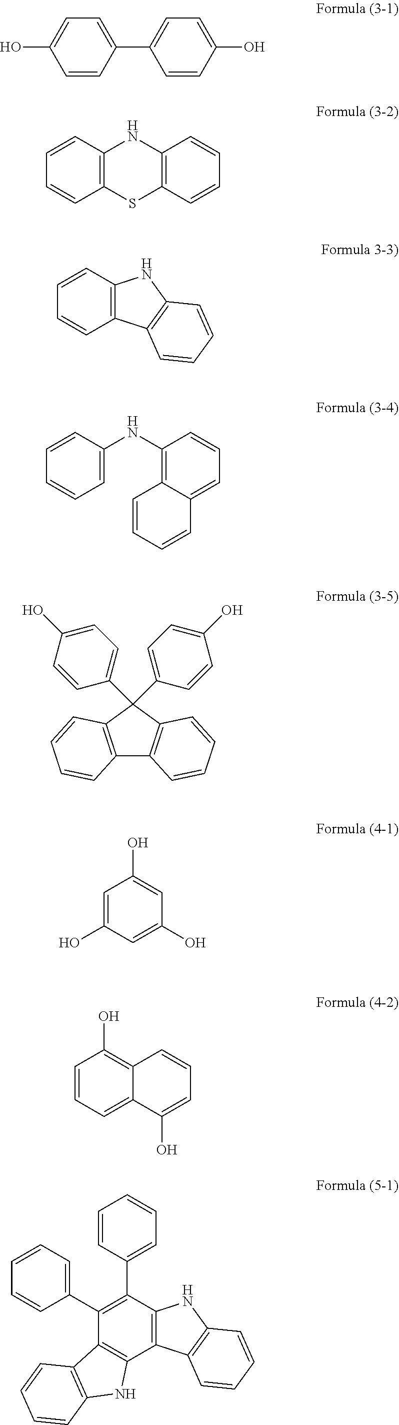

5. The method for improving hardness of a baked product according to any one of the above 1 to 4, comprising a step of
pre-baking the composition at 240° C. to 400° C. under an air atmosphere before baking the composition at 400° C. to 600° C. under an inert gas atmosphere.
6. A baked product of a composition including a compound containing one or more structures of the following Formula (1),
wherein hardness of the baked product is increased by 10% or more compared to hardness of a baked product baked at 350° C. under an air atmosphere.

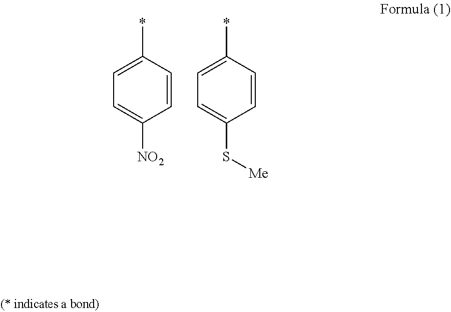

7. The baked product according to the above 6,
wherein the baked product is a baked product baked at 400° C. to 600° C. under an inert gas atmosphere.
   8. The baked product according to the above 6,
wherein the baked product is a baked product baked at 240° C. to 400° C. under an air atmosphere and then at 400° C. to 600° C. under an inert gas atmosphere.
   9. The baked product according to any one of the above 6 to 8,
wherein the compound contains a polymer structure having at least one repeating unit of the following Formula (2):

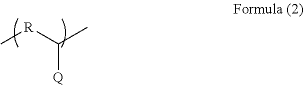

(wherein R is an organic group having an aromatic ring, a condensed aromatic ring, or a condensed aromatic heterocycle, and Q is one of the structures of Formula (1)).
10. The baked product according to the above 9,
wherein R is a divalent group in which hydrogen atoms on an aromatic ring having a structure of the following Formula (3), Formula (4), or Formula (5) are substituted:

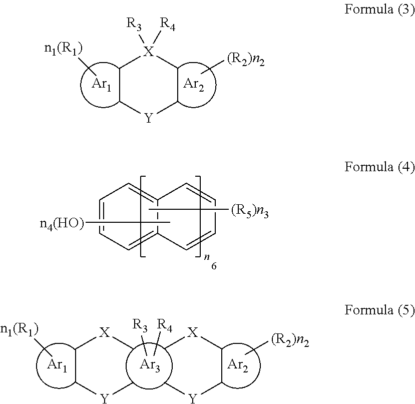

(in Formula (3), at least one of X and Y is present; X is a nitrogen atom or a carbon atom, Y is a single bond, a sulfur atom, or an oxygen atom; each of Ar₁ and Ar₂ is independently a benzene ring or a naphthalene ring which is arbitrarily substituted with R₁ or R₂, each of R₁ and R₂ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, or a combination thereof which arbitrarily contains an ether bond, a ketone bond, or an ester bond; each of n₁ and n₂ is an integer of 1 to 3 when Ar₁ and Ar₂ are benzene rings, and an integer of 1 to 5 when Ar₁ and Ar₂ are naphthalene rings; and each of R₃ and R₄ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, a phenyl group, a phenyl group substituted with a hydroxyl group, or a combination thereof which arbitrarily contains an ether bond, a ketone bond, or an ester bond; where, when X is a nitrogen atom, R₄ is absent; in Formula (4), R₅ is a C₁₋₃ alkyl group, n₃ is an integer of 0 to 4, n₄ is an integer of 1 to 4, and n₅ is any of 0, 1, and 2; and in Formula (5), Ar₁, Ar₂, R₁, R₂, R₃, R₄, n₁, and n₂ are the same as above, Ar₃ is a benzene ring or a naphthalene ring which is arbitrarily substituted with R₃ and R₄; and R₃ and R₄ are the same as above).
11. The baked product according to the above 9 or 10,
wherein R is a divalent group in which hydrogen atoms on an aromatic ring having any one of the following structures are substituted:

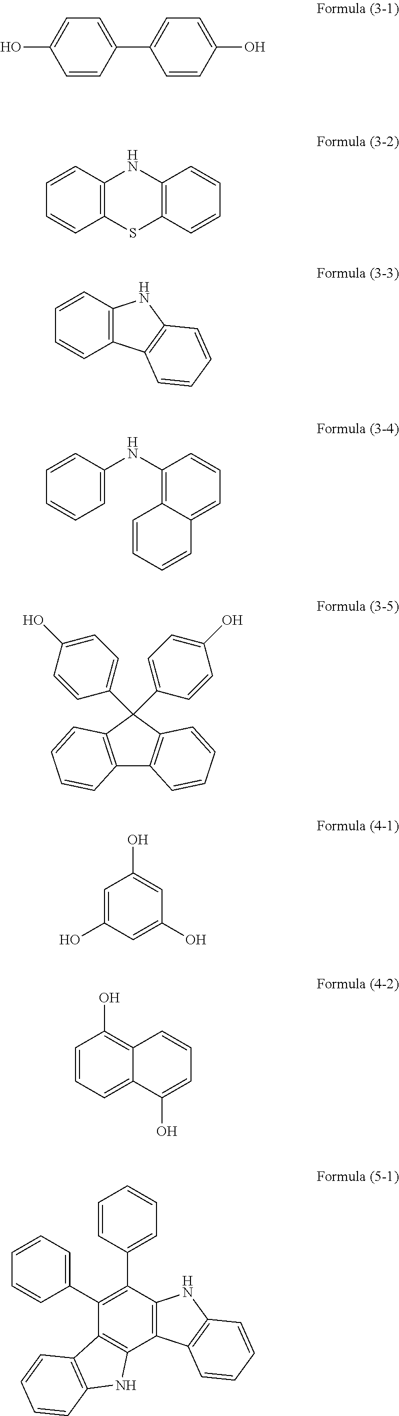

12. A resist underlayer film composed of the baked product according to any one of the above 6 to 11.
13. A method of producing a resist underlayer film, comprising a step of forming the resist underlayer film according to the above 12 on a semiconductor substrate.
14. A method of producing a semiconductor device, comprising:
a step of forming the resist underlayer film according to the above 12 on a semiconductor substrate;
a step of forming a resist film thereon;
a step of forming a resist pattern by emitting light or an electron beam and developing;
a step of etching the underlayer film using the formed resist pattern; and
a step of processing the semiconductor substrate using the patterned underlayer film.
   15. A method of producing a semiconductor device, comprising:
a step of forming the resist underlayer film according to the above 12 on a semiconductor substrate;
a step of forming a hard mask thereon;
a step of additionally forming a resist film thereon;
a step of forming a resist pattern by emitting light or an electron beam and developing;
a step of etching the hard mask using the formed resist pattern;
a step of etching the underlayer film using the patterned hard mask; and
a step of processing the semiconductor substrate using the patterned resist underlayer film.

### Effects of the Invention

By the method for improving the hardness of a baked product of the present invention, a baked product having a higher hardness than a baked product obtained by baking a composition including a compound containing one of the structures of Formula (1) at 350° C. under an air atmosphere is obtained.

In addition, in the resist underlayer film composed of the baked product, since hydrogen atoms bonded to carbon atoms on aromatic rings, condensed aromatic rings, or condensed aromatic heterocycles (for example, a benzene ring) in the unit structure of polymers contained in the baked product are substituted with chemical groups having specific functions, the film density and hardness are improved, the pattern bending resistance is high, the etching resistance is also improved, and finer substrate processing is achieved compared to resist underlayer films having polymers containing, in the unit structure, the aromatic rings, condensed aromatic rings, or condensed aromatic heterocycles which are not substituted with these chemical groups.

In addition, the resist underlayer film can be used as a flattening film, a resist underlayer film, a film for preventing contamination on a resist layer, and a film having dry etch selectivity. Therefore, it is possible to easily and accurately form a resist pattern in a lithography process for semiconductor production.

### MODES FOR CARRYING OUT THE INVENTION

### [Compound Containing One or More Structures of Formula (1)]

Specifically, a compound containing one or more structures of the following Formula (1) contains a polymer structure having at least one repeating unit of the following Formula (2).

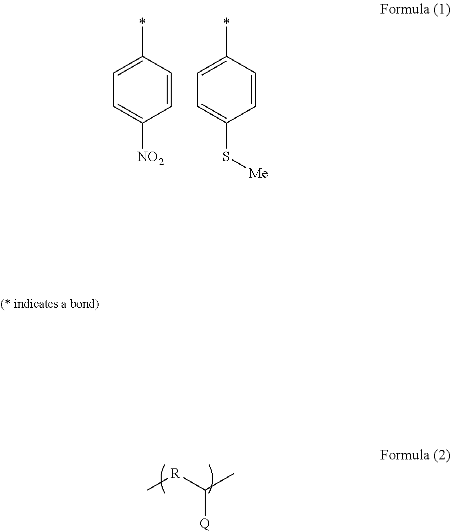

(wherein R is a divalent group having an aromatic ring, a condensed aromatic ring, or a condensed aromatic heterocycle, and Q is one of the structures of Formula (1)).

The aromatic ring, condensed aromatic ring, or condensed aromatic heterocycle may be one or more benzene rings, naphthalene rings, or condensed rings of a benzene ring and a heterocycle. Preferably, R is, for example, an organic group having benzene, naphthalene, carbazole, diphenylamine, trishydroxyphenylethane or the like.

In addition, R is a divalent group in which hydrogen atoms on an aromatic ring having a compound structure of the following Formula (3), Formula (4), or Formula (5) are substituted.

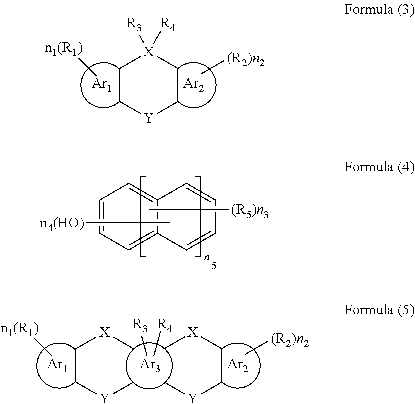

(in Formula (3), at least one of X and Y is present; X is a nitrogen atom or a carbon atom, Y is a single bond, a sulfur atom, or an oxygen atom; each of Ar₁ and Ar₂ is independently a benzene ring or a naphthalene ring which is arbitrarily substituted with R₁ or R₂, each of R₁ and R₂ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, or a combination thereof which arbitrarily contains an ether bond, a ketone bond, or an ester bond; each of n₁ and n₂ is an integer of 1 to 3 when Ar₁ and Ar₂ are benzene rings, and an integer of 1 to 5 when Ar₁ and Ar₂ are naphthalene rings; and each of R₃ and R₄ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, a phenyl group, a phenyl group substituted with a hydroxyl group, or a combination thereof which arbitrarily contains an ether bond, a ketone bond, or an ester bond; where, when X is a nitrogen atom, R₄ is absent; in Formula (4), R₅ is a C₁₋₃ alkyl group, n₃ is an integer of 0 to 4, n₄ is an integer of 1 to 4, and n₅ is any of 0, 1, and 2; and in Formula (5), Ar₁, Ar₂, R₁, R₂, R₃, R₄, n₁, and n₂ are the same as above, Ar₃ is a benzene ring or a naphthalene ring which is arbitrarily substituted with R₃ and R₄; and R₃ and R₄ are the same as above).

Examples of halogen atoms include a fluorine atom, a chlorine atom, a bromine atom, and an iodine atom.

Examples of C₁₋₁₀ alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group and 2-ethyl-3-methyl-cyclopropyl group.

The C₁₋₃ alkyl group is included in the above examples.

Examples of C₂₋₁₀ alkenyl groups include ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group and 3-cyclohexenyl group.

Examples of C₂₋₁₀ alkynyl groups include ethynyl group, 1-propynyl group, 2-propynyl group, 1-butynyl group, 2-butynyl group, 3-butynyl group, 3-pentynyl group, 4-methyl-1-pentynyl group, and 3-methyl-1-pentynyl group.

Specifically, R in Formula (2) is a divalent group in which hydrogen atoms on an aromatic ring having any one of the following structures are substituted.

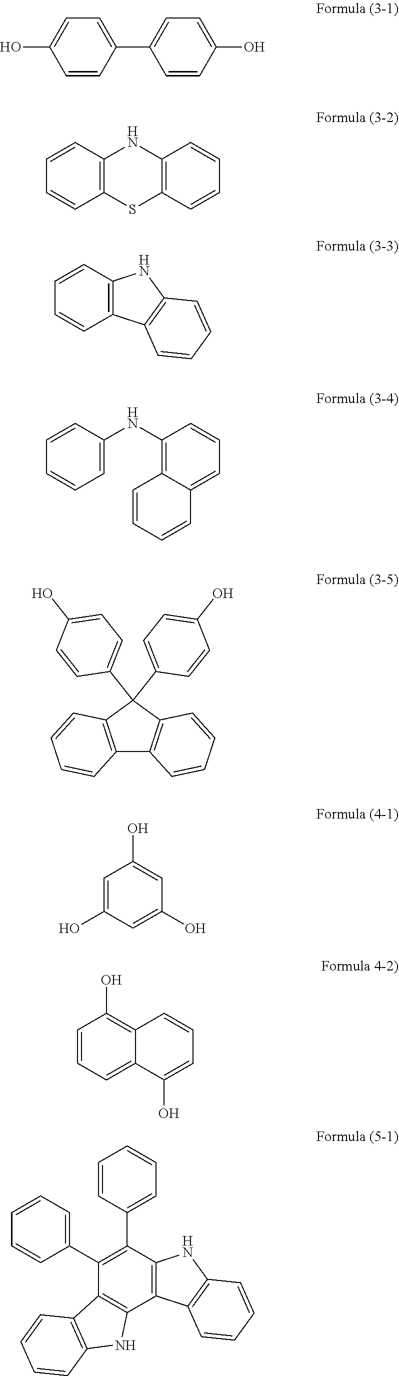

### [Composition Including Compound Containing One or More Structures of Formula (1)]

In the composition including a compound containing one or more structures of Formula (1), in addition to the compound (polymer) containing one or more structures of Formula (1), other polymers may be used by being mixed in an amount within 30 mass % based on the total polymer.

Examples of these polymers include polyacrylic acid ester compounds, polymethacrylic acid ester compounds, polyacrylamide compounds, polymethacrylamide compounds, polyvinyl compounds, polystyrene compounds, polymaleimide compounds, polymaleic anhydrides, and polyacrylonitrile compounds.

The composition of the present invention is a resist underlayer film-forming composition. The composition contains a compound containing one or more structures of Formula (1) (polymer), other polymers and a solvent. In addition, it can contain a crosslinking agent, and as necessary, additives such as a surfactant. The solid content of the composition is 0.1 to 70 mass % or 0.1 to 60 mass %. The solid content is the content proportion of all components excluding the solvent from the resist underlayer film-forming composition. The solid content may contain all the polymers in a proportion of 1 to 100 mass %, 1 to 99.9 mass %, or 50 to 99.9 mass %.

The polymer used in the present invention has a weight average molecular weight of 600 to 1,000,000 or 600 to 200,000.

The composition of the present invention can contain a crosslinking agent component. Examples of crosslinking agents include melamine-based agents, substituted urea-based agents and polymers thereof. A crosslinking agent having at least two crosslink-forming substituents is preferable, and is a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. In addition, a condensation product of these compounds can also be used.

In addition, as the crosslinking agent, a crosslinking agent having high heat resistance can be used. As the crosslinking agent having high heat resistance, a compound containing a crosslink-forming substituent having an aromatic ring (for example, a benzene ring or a naphthalene ring) in the molecule can be preferably used.

The crosslinking agent may be, for example, a compound having a substructure of the following Formula (6) or a polymer or oligomer having a repeating unit structure of the following Formula (7).

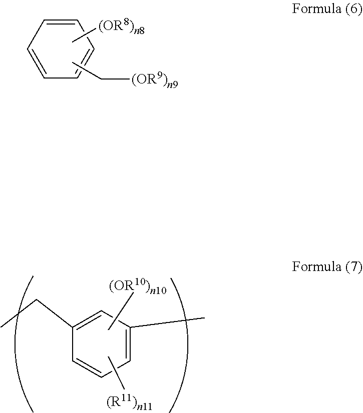

In Formula (6), each of R⁸ and R⁹ is a hydrogen atom, a C₁₋₁₀ alkyl group, or a C₆₋₂₀ aryl group, n₈ is an integer of 1 to 4, n₉ is an integer of 1 to (5-n₁), and (n₈+n₉) is an integer of 2 to 5.

In Formula (7), each R¹⁰ is a hydrogen atom or a C₁₋₁₀ alkyl group, R¹¹ is a C₁₋₁₀ alkyl group, n₁₀ is an integer of 1 to 4, and n₁₁ is 0 to (4-n₁₀), and (n₁₀+n₁₁) is an integer of 1 to 4. Oligomers and polymers having the number of repeating unit structures in a range of 2 to 100 or 2 to 50 can be used.

Examples of C₁₋₁₀ alkyl groups include those exemplified above. Examples of C₆₋₂₀ aryl groups include phenyl group, naphthyl group, and anthryl group.

Examples of compounds, polymers, and oligomers of Formula (6) and Formula (7) are shown below.

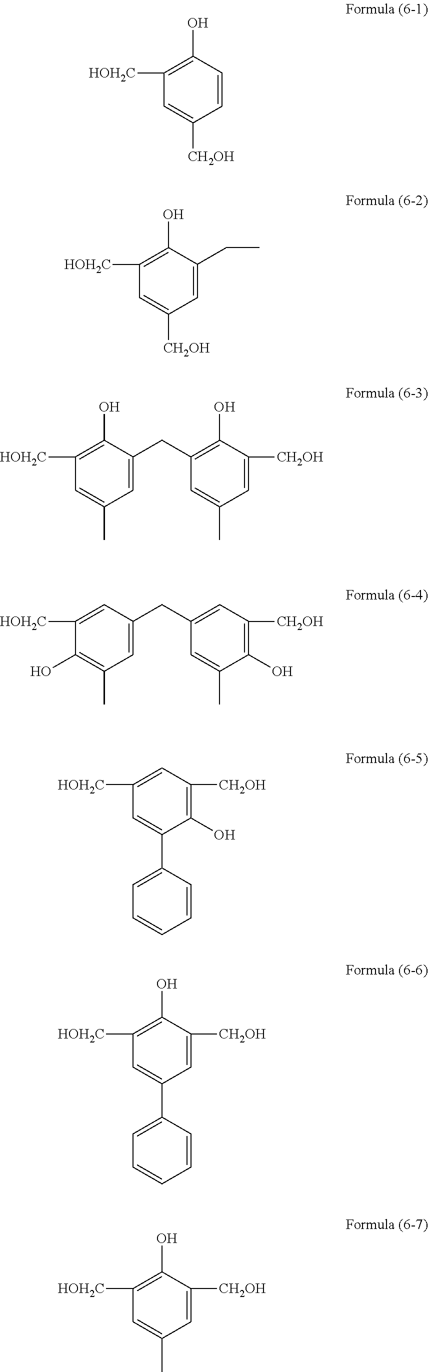

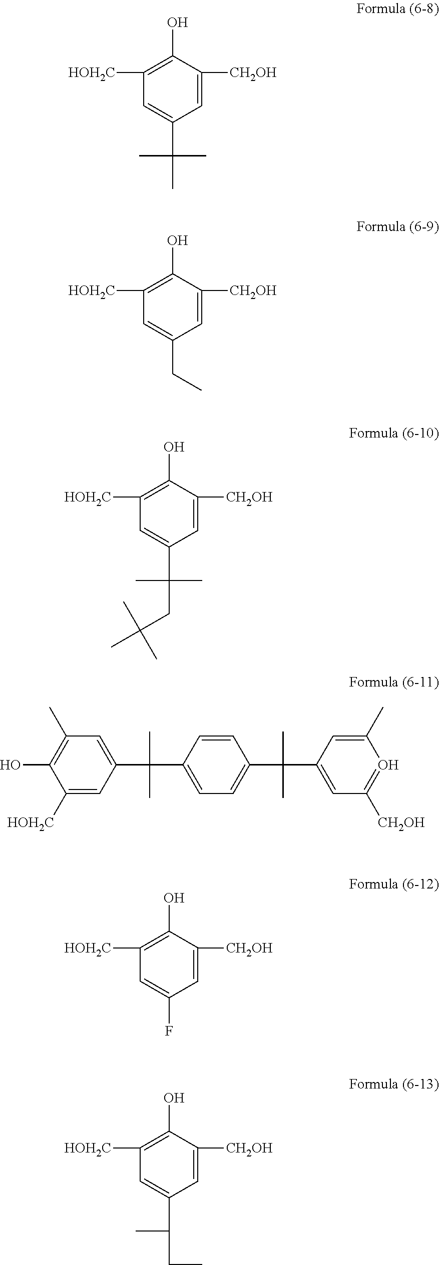

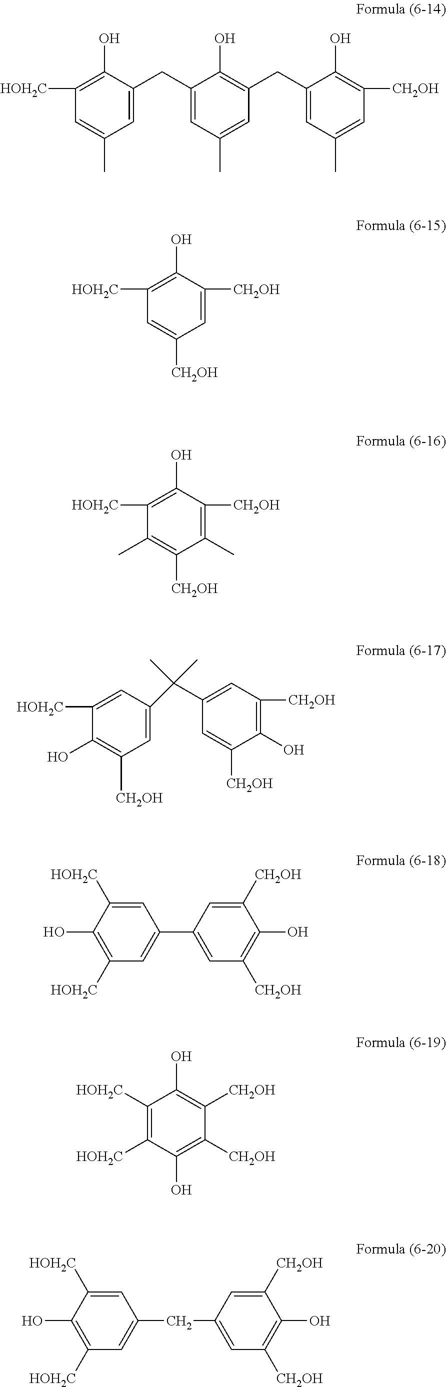

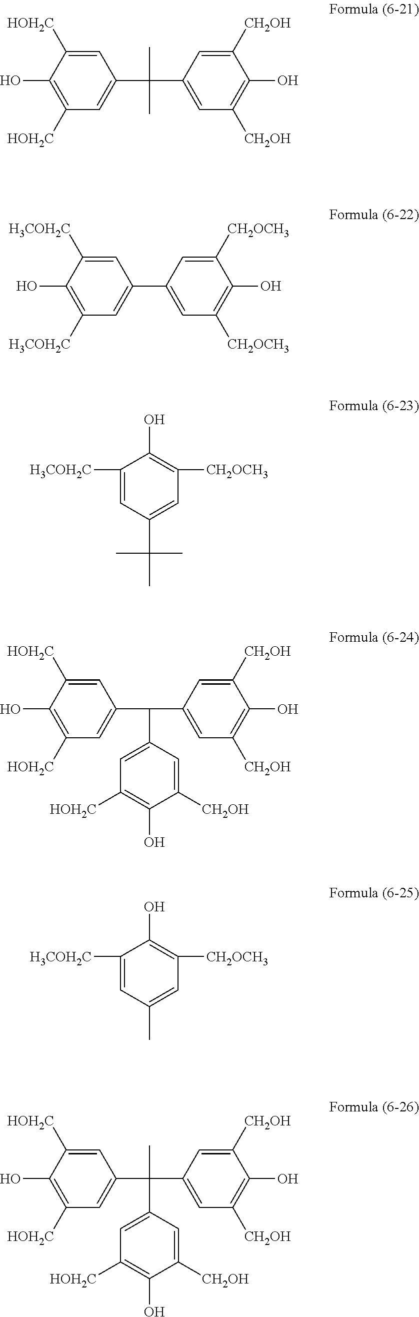

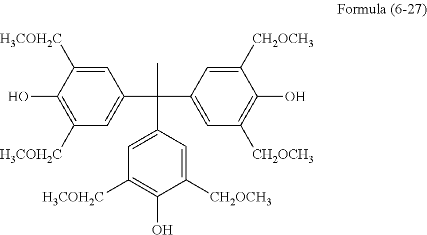

The compounds are available as products (commercially available from Asahi Yukizai Corporation and Honshu Chemical Industry Co., Ltd.). For example, among the crosslinking agents, the compound of Formula (6-21) is available as TM-BIP-A (product name, commercially available from Asahi Yukizai Corporation).

The amount of the crosslinking agent added varies depending on the coating solvent used, the base substrate used, the required solution viscosity, the required film shape or the like, and is 0.001 to 80 mass %, preferably 0.01 to 50 mass %, and more preferably 0.05 to 40 mass % with respect to a total solid content. These crosslinking agents may cause a crosslinking reaction due to self-condensation, but when there are crosslinkable substituents in the polymer of the present invention, a crosslinking reaction with these crosslinkable substituents may be caused.

The composition of the present invention may contain an acid and/or a salt thereof and/or an acid generating agent as a catalyst for promoting the crosslinking reaction.

Examples of acids include p-toluenesulfonic acid, trifluoromethanesulfonic acid, salicylic acid, 5-sulfosalicylic acid, 4-phenolsulfonic acid, camphorsulfonic acid, 4-chlorobenzenesulfonic acid, benzenedisulfonic acid, 1-naphthalenesulfonic acid, citric acid, benzoic acid, hydroxybenzoic acid, and naphthalenecarboxylic acid.

As the salt, salts of the above acids can be used. Although the salt is not limited, ammonia derivative salts such as trimethylamine salts and triethylamine salts, pyridine derivative salts, morpholine derivative salts and the like can be suitably used.

Acids and/or salts thereof can be used alone or two or more thereof can be used in combination. The amount added with respect to a total solid content is generally 0.0001 to 20 mass %, preferably 0.0005 to 10 mass %, and more preferably 0.01 to 5 mass %.

Examples of acid generating agents include thermal acid generating agents and photoacid generating agents.

Examples of thermal acid generating agents include 2,4,4,6-tetrabromocyclohexadienone, benzoin tosylate, 2-nitrobenzyl tosylate, K-PURE [registered trademark] CXC-1612, CXC-1614, TAG-2172, TAG-2179, TAG-2678, TAG2689, and TAG2700 (commercially available from King Industries), SI-45, SI-60, SI-80, SI-100, SI-110, and SI-150 (commercially available from Sanshin Chemical Industry Co., Ltd.), and other organic sulfonic acid alkyl esters.

The photoacid generating agent generates an acid when the resist is exposed. Therefore, the acidity of the underlayer film can be adjusted. This is a method for adjusting the acidity of the underlayer film to the acidity of the upper layer resist. In addition, when the acidity of the underlayer film is adjusted, it is possible to adjust the pattern shape of the resist formed on the upper layer.

Examples of photoacid generating agents contained in the resist underlayer film-forming composition for nanoimprinting of the present invention include onium salt compounds, sulfonimide compounds, and disulfonyldiazomethane compounds.

Examples of onium salt compounds include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl) iodonium camphorsulfonate and bis(4-tert-butylphenyl) iodonium trifluoromethanesulfonate, and sulfonium salt compounds such as triphenylsulfonium hexafluoroantimonate, triphenylsulfonium nonafluoro-n-butanesulfonate, triphenylsulfonium camphorsulfonate and triphenylsulfonium trifluoromethanesulfonate.

Examples of sulfonimide compounds include N-(trifluoromethanesulfonyloxy) succinimide, N-(nonafluoro-n-butanesulfonyloxy) succinimide, N-(camphorsulfonyloxy) succinimide and N-(trifluoromethanesulfonyloxy) naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

Acid generating agents can be used alone or two or more thereof can be used in combination.

When an acid generating agent is used, the proportion thereof with respect to a solid content of 100 parts by mass of the resist underlayer film-forming composition for nanoimprinting is 0.01 to 10 parts by mass, 0.1 to 8 parts by mass, or 0.5 to 5 parts by mass.

In the composition of the present invention used as a lithography coating type underlayer film-forming composition, in addition to the above components, a light absorbing agent, a rheology adjusting agent, an adhesive auxiliary agent, surfactant and the like can be additionally added as necessary.

As additional light absorbing agents, for example, commercially available light absorbing agents described in “A Technology and Market of Industrial Dyes” (CMC publishing Co., Ltd.) and “A Handbook of Dyes” (edited by The Society of Synthetic Organic Chemistry), for example, C. I. Disperse Yellow 1, 3, 4, 5, 7, 8, 13, 23, 31, 49, 50, 51, 54, 60, 64, 66, 68, 79, 82, 88, 90, 93, 102, 114 and 124; C. I. Disperse Orange 1, 5, 13, 25, 29, 30, 31, 44, 57, 72 and 73; C. I. Disperse Red 1, 5, 7, 13, 17, 19, 43, 50, 54, 58, 65, 72, 73, 88, 117, 137, 143, 199 and 210; C. I. Disperse Violet 43; C. I. Disperse Blue 96; C. I. Fluorescent Brightening Agent 112, 135 and 163; C. I. Solvent Orange 2 and 45; C. I. Solvent Red 1, 3, 8, 23, 24, 25, 27 and 49; C. I. Pigment Green 10; C. I. Pigment Brown 2 and the like can be suitably used. The light absorbing agent is added in a proportion of generally 10 mass % or less, and preferably 5 mass % or less with respect to a total solid content of the resist underlayer film-forming composition for lithography.

The rheology adjusting agent is mainly added in order to improve the fluidity of the resist underlayer film-forming composition, improve the uniformity of the film thickness of the resist underlayer film particularly in a baking step, and improve the ability of the resist underlayer film-forming composition to fill the hole. Specific examples thereof include phthalic acid derivatives such as dimethyl phthalate, diethyl phthalate, diisobutyl phthalate, dihexyl phthalate, and butyl isodecyl phthalate, adipic acid derivatives such as di-n-butyl adipate, diisobutyl adipate, diisooctyl adipate, and octyldecyl adipate, maleic acid derivatives such as di-n-butyl maleate, diethyl malate, and dinonyl maleate, oleic acid derivatives such as methyl oleate, butyl oleate, and tetrahydrofurfuryl oleate, and stearic acid derivatives such as n-butyl stearate and glyceryl stearate. These rheology adjusting agents are added in a proportion of generally less than 30 mass % with respect to a total solid content of the resist underlayer film-forming composition for lithography.

The adhesive auxiliary agent is mainly added in order to improve the adhesion between the substrate or the resist and the resist underlayer film-forming composition, and prevent the resist from peeling off particularly during development. Specific examples thereof include chlorosilanes such as trimethylchlorosilane, dimethylvinylchlorosilane, methyldiphenylchlorosilane, and chloromethyldimethylchlorosilane, alkoxysilanes such as trimethylmethoxysilane, dimethyldiethoxysilane, methyldimethoxysilane, dimethylvinylethoxysilane, diphenyldimethoxysilane, and phenyltriethoxysilane, silazanes such as hexamethyldisilazane, N,N′-bis(trimethylsilyl) urea, dimethyltrimethylsilylamine, and trimethylsilylimidazole, silanes such as vinyltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, ureas such as 1,1-dimethylurea and 1,3-dimethylurea, and thiourea compounds. These adhesive auxiliary agents are added in a proportion of generally less than 5 mass %, and preferably less than 2 mass % with respect to a total solid content of the resist underlayer film-forming composition for lithography.

In the composition of the present invention used as a resist underlayer film-forming composition for lithography, in order to prevent pinholes, striations or the like from being generated and further improve coverage against surface unevenness, a surfactant can be added. Examples of surfactants include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkyl allyl ethers such as polyoxyethylene octylphenol ether, and polyoxyethylene nonylphenol ether, sorbitan fatty acid esters such as polyoxyethylene-polyoxypropylene block copolymers, sorbitan monolaurate, sorbitan monopalmitate, sorbitan monostearate, sorbitan monooleate, sorbitan trioleate, and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine-based surfactants such as EFTOP EF301, EF303, and EF352 (product name, commercially available from Tohkem Products Corp.), Megaface F171, F173, R-30, R-40, and R-40N (product name, commercially available from DIC Corporation), Fluorad FC430 and FC431 (product name, commercially available from Sumitomo 3M Ltd.), AsahiGuard AG710, Surflon S-382, SC101, SC102, SC103, SC104, SC105, and SC106 (product name, commercially available from Asahi Glass Co., Ltd.), and organosiloxane polymer KP341 (commercially available from Shin-Etsu Chemical Co., Ltd.). The amount of these surfactants added is generally 2.0 mass % or less, and preferably 1.0 mass % or less with respect to a total solid content of the composition of the present invention to be used as a resist underlayer film-forming composition for lithography. These surfactants may be added alone or two or more thereof can be added in combination.

In the present invention, as a solvent for dissolving the polymers, crosslinking agent components, crosslinking catalysts and the like, ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methyl propionate, ethyl ethoxy acetate, ethyl hydroxy acetate, methyl 2-hydroxy-3-methyl butanoate, methyl 3-methoxy propionate, ethyl 3-methoxy propionate, ethyl 3-ethoxy propionate, methyl 3-ethoxy propionate, methyl pyruvate, ethyl pyruvate, ethyl acetate, butyl acetate, ethyl lactate, butyl lactate and the like can be used. These organic solvents are used alone or two or more thereof are used in combination.

In addition, high-boiling-point solvents such as propylene glycol monobutyl ether, and propylene glycol monobutyl ether acetate can be mixed and used. Among these solvents, propylene glycol monomethyl ether, propylene glycol monomethyl ether acetate, ethyl lactate, butyl lactate, cyclohexanone and the like are preferably used in order to improve leveling properties.

### [Method for Improving Hardness of Baked Product]

In the method for improving the hardness of a baked product of the present invention, a composition including a compound containing one or more structures of Formula (1) is baked at 400° C. to 600° C. under an inert gas atmosphere, and thus a baked product whose hardness is increased by 10% or more, preferably 15% or more, and more preferably 20% or more compared to the hardness of the baked product baked at 350° C. under an air atmosphere is obtained.

In addition, the method may include a step of pre-baking the composition at 240° C. to 400° C. under an air atmosphere before baking at 400° C. to 600° C. under an inert gas atmosphere.

Examples of inert gases include nitrogen.

The baking time may be selected according to conditions suitable for a process step of a desired electronic device and the baking time may be selected so that physical property values of the obtained film match required characteristics of the electronic device. The baking time is preferably 1 second to 300 seconds and more preferably 30 seconds to 120 seconds.

### [Methods of Producing Resist Underlayer Film and Semiconductor Device]

When the composition including a compound containing one or more structures of Formula (1) of the present invention is used as a resist underlayer film-forming composition for lithography, the baked product obtained by the method for improving the hardness of a baked product of the present invention is used as a resist underlayer film, and hereinafter, methods of producing a resist underlayer film and a semiconductor device will be described.

The resist underlayer film-forming composition is applied onto a substrate (for example, transparent substrates such as silicon/silicon dioxide-coated glass substrates and ITO substrates) used for producing precision integrated circuit elements by an appropriate coating method such as using a spinner or a coater, and then baked and cured to prepare a coating type underlayer film.

Here, as conditions for baking after coating, as described above, baking is performed at 400° C. to 600° C. under an inert gas atmosphere or pre-baking is performed at 240° C. to 400° C. under an air atmosphere and baking is then performed at 400° C. to 600° C. under an inert gas atmosphere for preparation. In addition, the film thickness of the resist underlayer film as the baked product is preferably 0.01 to 3.0 μm.

Then, a favorable resist pattern can be obtained by directly applying a resist on a resist underlayer film or by applying a resist after forming one or several coating material layers on a coating type underlayer film as necessary, emitting light or an electron beam through a predetermined mask, and performing developing, rinsing, and drying. As necessary, heating (post exposure bake: PEB) can be performed after light or an electron beam is emitted. Then, the resist underlayer film in the portion in which the resist has been developed and removed in the step is removed by dry etching, and a desired pattern can be formed on the substrate.

The resist used in the present invention is a photoresist or an electron beam resist.

The resist underlayer film composed of the baked product of the present invention can be used as a lithography resist underlayer film, and either a negative type or positive type photoresist can be used as the photoresist applied to the upper part of the resist underlayer film, and examples thereof include a positive-type photoresist composed of a novolac resin and 1,2-naphthoquinone diazide sulfonic acid ester, a chemically amplified photoresist composed of a binder having a group that decomposes with an acid and increases the alkaline dissolution rate and a photoacid generating agent, a chemically amplified photoresist composed of an alkali-soluble binder, a low-molecular-weight compound that decomposes with an acid and increases the alkaline dissolution rate of a photoresist, and a photoacid generating agent, a chemically amplified photoresist composed of a binder having a group that decomposes with an acid and increases the alkaline dissolution rate, a low-molecular-weight compound that decomposes with an acid and increases the alkaline dissolution rate of a photoresist, and a photoacid generating agent, and a photoresist having Si atoms in the framework, and for example, APEX-E (product name, commercially available from Rohm and Haas Company) can be used.

In addition, regarding the electron beam resist to be applied to the upper part of the lithography resist underlayer film, for example, a composition including a resin containing a Si—Si bond in the main chain and an aromatic ring at the end and an acid generating agent that generates an acid when an electron beam is emitted or a composition including poly(p-hydroxystyrene) in which a hydroxyl group is substituted with an organic group containing N-carboxyamine and an acid generating agent that generates an acid when an electron beam is emitted may be used. In the latter electron beam resist composition, an acid generated from the acid generating agent when an electron beam is emitted reacts with the N-carboxyaminooxy group on the polymer side chain, the polymer side chain decomposes into a hydroxyl group, becomes alkali-soluble, and dissolves in an alkaline developing solution, and a resist pattern is formed. Examples of acid generating agents that generate an acid when an electron beam is emitted include halogenated organic compounds such as 1,1-bis [p-chlorophenyl]-2,2,2-trichloroethane, 1,1-bis [p-methoxyphenyl]-2,2,2-trichloroethane, 1,1-bis [p-chlorophenyl]-2,2-dichloroethane, and 2-chloro-6-(trichloromethyl)pyridine, onium salts such as triphenylsulfonium salts and diphenyliodonium salts, and sulfonates such as nitrobenzyl tosylate and dinitrobenzyl tosylate.

After a resist solution is applied, baking is performed at a baking temperature of 70 to 150° C. for a baking time of 0.5 to 5 minutes, and a resist film with a thickness in a range of 10 to 1,000 nm is obtained. The resist solution, the developing solution, and the following coating material can be coated by a spin coating, a dipping method, a spraying method or the like, and a spin coating method is particularly preferable. The resist is exposed through a predetermined mask. For exposure, a KrF excimer laser (with a wavelength of 248 nm), an ArF excimer laser (with a wavelength of 193 nm) and an EUV light (with a wavelength of 13.5 nm), an electron beam and the like can be used. After exposure, heating after exposure (post exposure bake (PEB)) can be performed as necessary. Heating after exposure is performed by appropriately selecting the heating temperature from 70° C. to 150° C. and the heating time from 0.3 to 10 minutes.

As the developing solution for the resist having the resist underlayer film, aqueous solutions of alkalis, for example, inorganic alkalis such as sodium hydroxide, potassium hydroxide, sodium carbonate, sodium silicate, sodium metasilicate, and ammonia water, primary amines such as ethylamine and n-propylamine, secondary amines such as diethylamine and di-n-butylamine, tertiary amines such as triethylamine and methyl diethylamine, alcohol amines such as dimethylethanolamine and triethanolamine, quaternary ammonium salts such as tetramethylammonium hydroxide, tetraethylammonium hydroxide, and choline, and cyclic amines such as pyrrole and piperidine can be used. In addition, the aqueous solution of alkalis to which appropriate amounts of alcohols such as isopropyl alcohol and nonionic surfactants are added can be used. Among these, the developing solution is preferably quaternary ammonium salts, and more preferably tetramethylammonium hydroxide and choline.

In addition, in the present invention, an organic solvent can be used as a developing solution for developing the resist. After the resist is exposed, development is performed with a developing solution (solvent). Therefore, for example, when a positive-type photoresist is used, the photoresist in the unexposed portion is removed, and a photoresist pattern is formed.

Examples of developing solutions include methyl acetate, butyl acetate, ethyl acetate, isopropyl acetate, amyl acetate, isoamyl acetate, ethyl methoxy acetate, ethyl ethoxy acetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. In addition, a surfactant and the like can be added to these developing solutions. Developing conditions are appropriately selected from among a temperature of 5 to 50° C. and a time of 10 to 600 seconds.

In the present invention, a semiconductor device can be produced through a step of forming a resist underlayer film composed of the baked product of the present invention on a semiconductor substrate, a step of forming a resist film thereon, a step of forming a resist pattern by emitting light or an electron beam and developing, a step of etching the resist underlayer film using the formed resist pattern and a step of processing the semiconductor substrate using the patterned resist underlayer film.

In the future, as resist patterns become finer, resolution problems and problems such as resist patterns collapsing after development will occur, and there will be a demand for thinner resists. Therefore, it is difficult to obtain a resist pattern film thickness sufficient for substrate processing, and a process in which not only the resist pattern but also the resist underlayer film formed between the resist and the semiconductor substrate to be processed can function as a mask during substrate processing has become required. Unlike conventional resist underlayer films with high etch rates, as resist underlayer films for such processes, there are demands for lithography resist underlayer films having a dry etching rate selectivity close to that of the resist, lithography resist underlayer films having a dry etching rate selectivity smaller than that of the resist, and lithography resist underlayer films having a dry etching rate selectivity smaller than that of the semiconductor substrate. In addition, it is possible to impart anti-reflection properties to such resist underlayer films, and it can have functions of conventional anti-reflective films.

On the other hand, in order to obtain a fine resist pattern, a process in which, when the resist underlayer film is dry-etched, the resist pattern and the resist underlayer film are made narrower than the pattern width when the resist is developed is also beginning to be used. Unlike conventional high etch rate anti-reflective films, as resist underlayer films for such processes, there are demands for resist underlayer films having a dry etching rate selectivity close to that of the resist. In addition, it is possible to impart anti-reflection properties to such resist underlayer films, and it can have functions of conventional anti-reflective films.

In the present invention, the baked product of the present invention, which is a resist underlayer film, is formed on a substrate, and then a resist can be applied directly onto the baked product, which is the resist underlayer film, or after one or several coating material layers are formed as necessary. Therefore, even if the width of the resist pattern becomes narrow and the resist is thinly coated to prevent pattern collapse, the substrate can be processed by selecting an appropriate etching gas.

That is, a semiconductor device can be produced through a step of forming a resist underlayer film composed of the baked product of the present invention on a semiconductor substrate, a step of forming a hard mask (for example, silicon oxynitride) using a coating material containing a silicon component and the like or a hard mask by vapor deposition thereon, a step of additionally forming a resist film thereon, a step of forming a resist pattern by emitting light or an electron beam and developing, a step of etching the hard mask with a halogen gas using the formed resist pattern, a step of etching the resist underlayer film with oxygen gas or hydrogen gas using the patterned hard mask, and a step of processing the semiconductor substrate with a halogen gas using the patterned resist underlayer film.

The composition including a compound containing one or more structures of Formula (1) of the present invention has high thermal stability, can prevent contamination on an upper layer film caused by decomposition products during baking, and enables a temperature margin allowance in the baking step.

In addition, the composition including a compound containing one or more structures of Formula (1) of the present invention can be used as a film having a function of preventing light reflection depending on process conditions and also having a function of preventing interaction between the substrate and the photoresist or preventing adverse effects of materials used in the photoresist or substances generated during exposure to the photoresist on the substrate.

### EXAMPLES

The weight average molecular weight shown in the following synthesis examples in this specification is the result measured through gel permeation chromatography (hereinafter abbreviated as GPC in this specification). For the measurement, a GPC device (HLC-8320 GPC, commercially available from Tosoh Corporation) was used, and measurement conditions and the like are as follows.
GPC column: TSKgel SuperH-RC, TSKgel SuperMultipore HZ-N, TSKgel SuperMultipore HZ-N (commercially available from Tosoh Corporation)
Column temperature: 40° C.
Solvent: tetrahydrofuran (for high-performance liquid chromatography, commercially available from Kanto Chemical Co., Inc.)
Standard sample: polystyrene (commercially available from Shodex)

### <Synthesis Example 1> (Synthesis of Polymer (1))

Under nitrogen, 7 g (55.51 mmol) of phloroglucinol (anhydrous) (commercially available from Tokyo Chemical Industry Co., Ltd.), 8.38 g (55.51 mmol) of 4-nitrobenzaldehyde (commercially available from Kanto Chemical Co., Inc.), and 46.15 g of propylene glycol monomethyl ether acetate were put into a 200 mL-capacity two-neck flask, and the mixture was heated to 140° C. and stirred under reflux for 14 hours. The obtained reaction mixture was added dropwise to 600 mL of methanol (commercially available from Kanto Chemical Co., Inc., special grade) to precipitate a polymer (1). When the molecular weight of this polymer was measured through GPC (in terms of polystyrene standards), the weight average molecular weight (Mw) was 1,357. Then, the polymer (1) was prepared as propylene glycol monomethyl ether solution having a solid content of 25 wt %, and the solution was stirred with a cation exchange resin and an anion exchange resin for 4 hours and then filtered to obtain a 20.80 wt % resin solution (1).

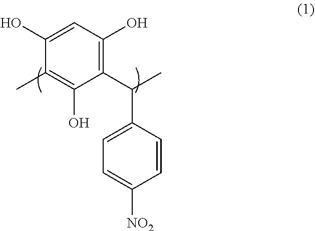

### <Synthesis Example 2> (Synthesis of Polymer (2))

Under nitrogen, 7 g (37.62 mmol) of 4,4′-dihydroxybiphenyl (commercially available from Tokyo Chemical Industry Co., Ltd.), 6.25 g (41.38 mmol) of 4-nitrobenzaldehyde (commercially available from Kanto Chemical Co., Inc.), 0.79 g (8.28 mmmol) of methanesulfonic acid (commercially available from Tokyo Chemical Industry Co., Ltd.), and 21.23 g of propylene glycol monomethyl ether acetate were put into a 200 mL-capacity two-neck flask, and the mixture was heated to 140° C. and stirred under reflux for 36 hours. The obtained reaction mixture was added dropwise to 190 mL of methanol (commercially available from Kanto Chemical Co., Inc., special grade)/pure water=3/7 to precipitate a polymer (2). When the molecular weight of this polymer was measured through GPC (in terms of polystyrene standards), the weight average molecular weight (Mw) was 874. Then, the polymer (2) was prepared as a propylene glycol monomethyl ether acetate solution having a solid content of 40 wt %, and the solution was stirred with a cation exchange resin and an anion exchange resin for 4 hours and then filtered to obtain a 36.69 wt % resin solution (2).

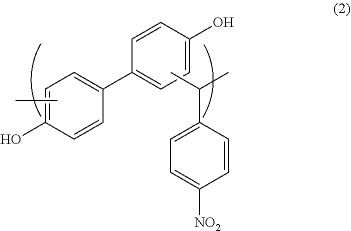

### <Synthesis Example 3> (Synthesis of Polymer (3))

Under nitrogen, 15 g (75.27 mmol) of phenothiazine (commercially available from Tokyo Chemical Industry Co., Ltd.), 11.37 g (75.27 mmol) of 4-nitrobenzaldehyde (commercially available from Kanto Chemical Co., Inc.), 0.36 g (3.76 mmmol) of methanesulfonic acid (commercially available from Tokyo Chemical Industry Co., Ltd.), and 59.64 g of propylene glycol monomethyl ether acetate were put into a 200 mL-capacity two-neck flask, and the mixture was heated to 100° C. and stirred under reflux for 24 hours. The obtained reaction mixture was added dropwise to 780 mL of methanol (commercially available from Kanto Chemical Co., Inc., special grade) to precipitate a polymer (1). When the molecular weight of this polymer was measured through GPC (in terms of polystyrene standards), the weight average molecular weight (Mw) was 1,034. Then, the polymer (3) was prepared as a cyclohexanone solution having a solid content of 30 wt %, and the solution was stirred with a cation exchange resin and an anion exchange resin for 4 hours and then filtered to obtain a 28.41 wt % resin solution (3).

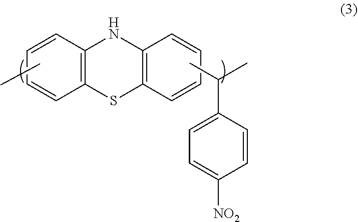

### <Synthesis Example 4> (Synthesis of Polymer (4))

Under nitrogen, 7 g (89.71 mmol) of carbazole (commercially available from Tokyo Chemical Industry Co., Ltd.), 13.55 g (89.71 mmol) of 4-nitrobenzaldehyde (commercially available from Kanto Chemical Co., Inc.), 0.25 g (2.69 mmmol) of methanesulfonic acid (commercially available from Tokyo Chemical Industry Co., Ltd.) and 59.74 g of propylene glycol monomethyl ether acetate were put into a 200 mL-capacity two-neck flask, and the mixture was heated to 140° C. and stirred under reflux for 24 hours. The obtained reaction mixture was added dropwise to 780 mL of methanol (commercially available from Kanto Chemical Co., Inc., special grade) to precipitate a polymer (4). When the molecular weight of this polymer was measured through GPC (in terms of polystyrene standards), the weight average molecular weight (Mw) was 1,798. Then, the polymer (4) was prepared as a propylene glycol monomethyl ether acetate solution having a solid content of 30 wt %, and the solution was stirred with a cation exchange resin and an anion exchange resin for 4 hours and then filtered to obtain a 27.86 wt % resin solution (4).

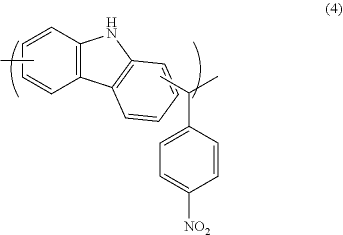

### <Synthesis Example 5> (Synthesis of Polymer (5))

Under nitrogen, 15 g (68.46 mmol) of N-phenyl-1-naphthylamine (commercially available from Tokyo Chemical Industry Co., Ltd.), 26.51 g (175.53 mmol) of 4-nitrobenzaldehyde (commercially available from Kanto Chemical Co., Inc.), 0.42 g (4.39 mmmol) of methanesulfonic acid (commercially available from Tokyo Chemical Industry Co., Ltd.), and 42.53 g of propylene glycol monomethyl ether acetate were put into a 200 mL-capacity two-neck flask, and the mixture was heated to 140° C. and stirred under reflux for 3 hours. The obtained reaction mixture was added dropwise to 760 mL of methanol (commercially available from Kanto Chemical Co., Inc., special grade) to precipitate a polymer (5). When the molecular weight of this polymer was measured through GPC (in terms of polystyrene standards), the weight average molecular weight (Mw) was 2,260. Then, the polymer (5) was prepared as a propylene glycol monomethyl ether acetate solution having a solid content of 25 wt %, and the solution was stirred with a cation exchange resin and an anion exchange resin for 4 hours and then filtered to obtain a 21.19 wt % resin solution (5).

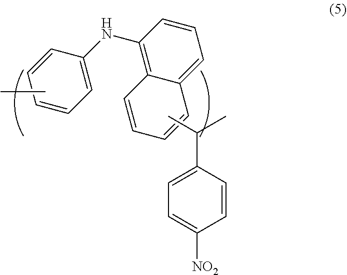

### <Synthesis Example 6> (Synthesis of Polymer (6))

Under nitrogen, 8 g (49.95 mmol) of 1,5-dihydroxynaphthalene (commercially available from Tokyo Chemical Industry Co., Ltd.), 7.54 g (49.95 mmol) of 4-nitrobenzaldehyde (commercially available from Kanto Chemical Co., Inc.), 0.48 g (4.99 mmmol) of methanesulfonic acid (commercially available from Tokyo Chemical Industry Co., Ltd.), and 51.83 g of propylene glycol monomethyl ether acetate were put into a 200 mL-capacity two-neck flask, and the mixture was heated to 140° C. and stirred under reflux for 5 hours. The obtained reaction mixture was added dropwise to 610 mL of methanol (commercially available from Kanto Chemical Co., Inc., special grade) to precipitate a polymer (6). When the molecular weight of this polymer was measured through GPC (in terms of polystyrene standards), the weight average molecular weight (Mw) was 6,521. Then, the polymer (6) was prepared as a propylene glycol monomethyl ether acetate solution having a solid content of 25 wt %, and the solution was stirred with a cation exchange resin and an anion exchange resin for 4 hours and then filtered to obtain a 20.79 wt % resin solution (6).

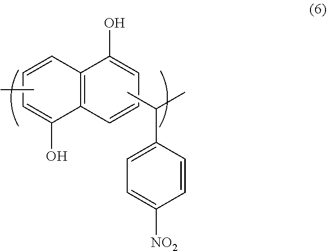

### <Synthesis Example 7> (Synthesis of Polymer (7))

Under nitrogen, 5 g (39.65 mmol) of phloroglucinol (anhydrous) (commercially available from Tokyo Chemical Industry Co., Ltd.), 6.63 g (43.61 mmol) of 4-(methylthio)benzaldehyde (commercially available from Tokyo Chemical Industry Co., Ltd.), and 34.89 g of propylene glycol monomethyl ether acetate were put into a 200 mL-capacity two-neck flask, and the mixture was heated to 140° C. and stirred under reflux for 3 hours. The obtained reaction mixture was added dropwise to 420 mL of methanol (commercially available from Kanto Chemical Co., Inc., special grade) to precipitate a polymer (7). When the molecular weight of this polymer was measured through GPC (in terms of polystyrene standards), the weight average molecular weight (Mw) was 7,066. Then, the polymer (7) was prepared as a propylene glycol monomethyl ether solution having a solid content of 20 wt %, and the solution was stirred with a cation exchange resin and an anion exchange resin for 4 hours and then filtered to a 15.26 wt % resin solution (7).

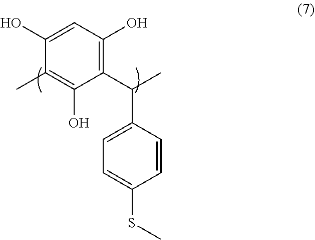

### <Synthesis Example 8> (Synthesis of Polymer (8))

Under nitrogen, 10 g (65.70 mmol) of phenothiazine (commercially available from Tokyo Chemical Industry Co., Ltd.), 13.09 g (65.70 mmol) of 4-(methylthio)benzaldehyde (commercially available from Kanto Chemical Co., Inc.), 0.31 g (3.23 mmmol) of methanesulfonic acid (commercially available from Tokyo Chemical Industry Co., Ltd.), and 68.96 g of propylene glycol monomethyl ether acetate were put into a 200 mL-capacity two-neck flask, and the mixture was heated to 100° C. and stirred under reflux for 24 hours. The obtained reaction mixture was added dropwise to 830 mL of methanol (commercially available from Kanto Chemical Co., Inc., special grade) to precipitate a polymer (8). When the molecular weight of this polymer was measured through GPC (in terms of polystyrene standards), the weight average molecular weight (Mw) was 1,966. Then, the polymer (8) was prepared as a cyclohexanone solution having a solid content of 30 wt %, and the solution was stirred with a cation exchange resin and an anion exchange resin for 4 hours and then filtered to obtain a 28.21 wt % resin solution (8).

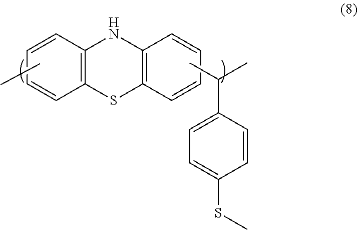

### <Synthesis Example 9> (Synthesis of Polymer (9))

Under nitrogen, 12.0 g (29.40 mmol) of diphenylindolocarbazole (refer to Synthesis Example 1 in WO2017/094780), 4.88 g (32.34 mmol) of 4-nitrobenzaldehyde (commercially available from Kanto Chemical Co., Inc.), 0.31 g (3.23 mmmol) of methanesulfonic acid (commercially available from Tokyo Chemical Industry Co., Ltd.) and 50.34 g of propylene glycol monomethyl ether acetate were put into a 200 mL-capacity two-neck flask, and the mixture was heated to 140° C. and stirred under reflux for 2 hours. The obtained reaction mixture was added dropwise to 610 mL of methanol (commercially available from Kanto Chemical Co., Inc., special grade) to precipitate a polymer (9). When the molecular weight of this polymer was measured through GPC (in terms of polystyrene standards), the weight average molecular weight (Mw) was 1,966. Then, the polymer (9) was prepared as a propylene glycol monomethyl ether acetate solution having a solid content of 30 wt %, and the solution was stirred with a cation exchange resin and an anion exchange resin for 4 hours and then filtered to obtain a 27.22 wt % resin solution (9).

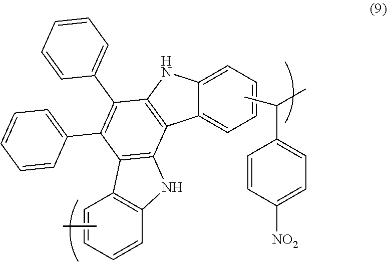

### <Comparative Synthesis Example 1> (Synthesis of Polymer 10)

Under nitrogen, 6 g (47.58 mmol) of phloroglucinol (anhydrous) (commercially available from Tokyo Chemical Industry Co., Ltd.), 5.44 g (52.34 mmol) of benzaldehyde (commercially available from Kanto Chemical Co., Inc.), 0.12 g of methanesulfonic acid (commercially available from Tokyo Chemical Industry Co., Ltd.), and 34.21 g of propylene glycol monomethyl ether acetate were put into a 200 mL-capacity two-neck flask, and the mixture was heated to 40° C. and stirred under reflux for 18 hours. The obtained reaction mixture was added dropwise to 500 mL of methanol (commercially available from Kanto Chemical Co., Inc., special grade)/pure water=3/7 to precipitate a polymer (10). When the molecular weight of this polymer was measured through GPC (in terms of polystyrene standards), the weight average molecular weight (Mw) was 2,662. Then, the polymer (10) was prepared as a propylene glycol monomethyl ether solution having a solid content of 30 wt %, and the solution was stirred with a cation exchange resin and an anion exchange resin for 4 hours and then filtered to obtain a 24.10 wt % resin solution (10).

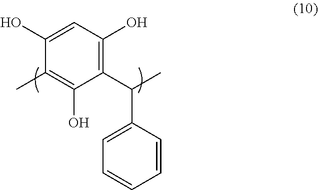

### <Comparative Synthesis Example 2> (Synthesis of Polymer 11)

Under nitrogen, 7 g (55.51 mmol) of phloroglucinol (anhydrous) (commercially available from Tokyo Chemical Industry Co., Ltd.), 10.11 g (55.51 mmol) of 4-phenylbenzaldehyde (commercially available from Kanto Chemical Co., Inc.) and 51.34 g of propylene glycol monomethyl ether acetate were put into a 200 mL-capacity two-neck flask, and the mixture was heated to 140° C. and stirred under reflux for 19 hours. The obtained reaction mixture was added dropwise to 420 mL of methanol (commercially available from Kanto Chemical Co., Inc., special grade)/pure water=3/7 to precipitate a polymer (11). When the molecular weight of this polymer was measured through GPC (in terms of polystyrene standards), the weight average molecular weight (Mw) was 6,699. Then, the polymer (11) was prepared as a propylene glycol monomethyl ether acetate solution having a solid content of 30 wt % and the solution was stirred with a cation exchange resin and an anion exchange resin for 4 hours and then filtered to obtain a 22.10 wt % resin solution (11).

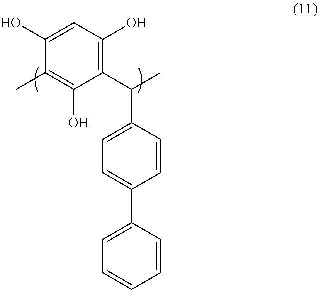

### <Comparative Synthesis Example 3> (Synthesis of Polymer 12)

Under nitrogen, 10 g (59.86 mmol) of carbazole (commercially available from Tokyo Chemical Industry Co., Ltd.), 6.35 g (59.86 mmol) of benzaldehyde (commercially available from Kanto Chemical Co., Inc.), 1.15 g (11.97 mmmol) of methanesulfonic acid (commercially available from Tokyo Chemical Industry Co., Ltd.) and 37.00 g of propylene glycol monomethyl ether acetate were put into a 200 mL-capacity two-neck flask, and the mixture was heated to 140° C. and stirred under reflux for 9 hours. The obtained reaction mixture was added dropwise to 490 mL of methanol (commercially available from Kanto Chemical Co., Inc., special grade) to precipitate a polymer (12). When the molecular weight of this polymer was measured through GPC (in terms of polystyrene standards), the weight average molecular weight (Mw) was 3,370. Then, the polymer (12) was prepared as a propylene glycol monomethyl ether acetate solution having a solid content of 30 wt %, and the solution was stirred with a cation exchange resin and an anion exchange resin for 4 hours and then filtered to obtain a 28.01 wt % resin solution (12).

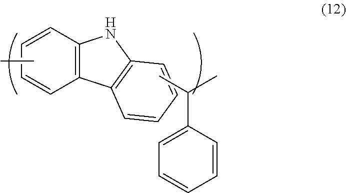

### <Comparative Synthesis Example 4> (Synthesis of Polymer 13)

Under nitrogen, 10.0 g (94.23 mmol) of phenothiazine (commercially available from Tokyo Chemical Industry Co., Ltd.), 18.77 g (94.23 mmol) of benzaldehyde (commercially available from Kanto Chemical Co., Inc.), 0.45 g (4.71 mmmol) of methanesulfonic acid (commercially available from Tokyo Chemical Industry Co., Ltd.), and 85.88 g of propylene glycol monomethyl ether acetate were put into a 200 mL-capacity two-neck flask, and the mixture was heated to 100° C. and stirred under reflux for 24 hours. The obtained reaction mixture was added dropwise to 1,000 mL of methanol (commercially available from Kanto Chemical Co., Inc., special grade) to precipitate a polymer (13). When the molecular weight of this polymer was measured through GPC (in terms of polystyrene standards), the weight average molecular weight (Mw) was 3,271. Then, the polymer (13) was prepared as a cyclohexanone solution having a solid content of 30 wt %, and the solution was stirred with a cation exchange resin and an anion exchange resin for 4 hours and then filtered to obtain a 26.79 wt % resin solution (13).

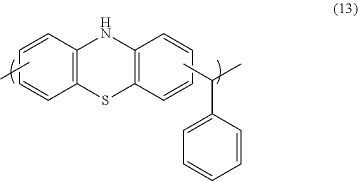

### <Comparative Synthesis Example 5> (Synthesis of Polymer 14)

Under nitrogen, 8 g (47.31 mmol) of carbazole (commercially available from Tokyo Chemical Industry Co., Ltd.), 7.10 g (47.31 mmol) of 4-carboxybenzaldehyde (commercially available from Tokyo Chemical Industry Co., Ltd.), 0.91 g (9.46 mmmol) of methanesulfonic acid (commercially available from Tokyo Chemical Industry Co., Ltd.), and 50.34 g of propylene glycol monomethyl ether acetate were put into a 200 mL-capacity two-neck flask, and the mixture was heated to 140° C. and stirred under reflux for 5 hours. The obtained reaction mixture was added dropwise to 600 mL of methanol (commercially available from Kanto Chemical Co., Inc., special grade) to precipitate a polymer (14). When the molecular weight of this polymer was measured through GPC (in terms of polystyrene standards), the weight average molecular weight (Mw) was 13,031. Then, the polymer (14) was prepared as a propylene glycol monomethyl ether acetate solution having a solid content of 30 wt %, and the solution was stirred with a cation exchange resin and an anion exchange resin for 4 hours and then filtered to obtain a 25 wt % resin solution (14).

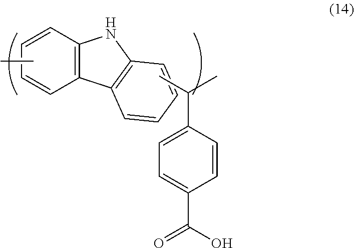

### <Comparative Synthesis Example 6> (Synthesis of Polymer 15)

Under nitrogen, 10.00 g (59.86 mmol) of carbazole (commercially available from Tokyo Chemical Industry Co., Ltd.), 11.49 g (59.86 mmol) of 4-amyloxybenzaldehyde (commercially available from Tokyo Chemical Industry Co., Ltd.), 1.15 g (11.97 mmmol) of methanesulfonic acid (commercially available from Tokyo Chemical Industry Co., Ltd.), and 49.01 g of propylene glycol monomethyl ether acetate were put into a 200 mL-capacity two-neck flask, and the mixture was heated to 140° C. and stirred under reflux for 5 hours. The obtained reaction mixture was added dropwise to 650 mL of methanol (commercially available from Kanto Chemical Co., Inc., special grade) to precipitate a polymer (15). When the molecular weight of this polymer was measured through GPC (in terms of polystyrene standards), the weight average molecular weight (Mw) was 4,001. Then, the polymer (15) was prepared as a propylene glycol monomethyl ether acetate solution having a solid content of 30 wt %, and the solution was stirred with a cation exchange resin and an anion exchange resin for 4 hours and then filtered to obtain a 25 wt % resin solution (15).

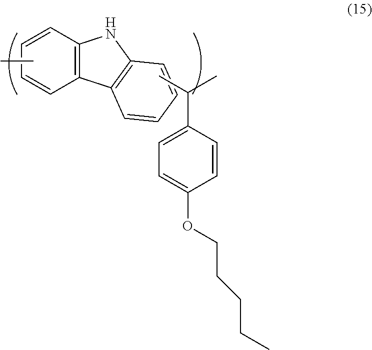

### <Comparative Synthesis Example 7> (Synthesis of Polymer 16)

Under nitrogen, 6 g (47.58 mmol) of phloroglucinol (anhydrous) (commercially available from Tokyo Chemical Industry Co., Ltd.), 7.32 g (52.34 mmol) of 4-chlorobenzaldehyde (commercially available from Tokyo Chemical Industry Co., Ltd.), and 44.42 g of propylene glycol monomethyl ether acetate were put into a 200 mL-capacity two-neck flask, and the mixture was heated to 140° C. and stirred under reflux for 19 hours. The obtained reaction mixture was added dropwise to 520 mL of methanol (commercially available from Kanto Chemical Co., Inc., special grade) to precipitate a polymer (16). When the molecular weight of this polymer was measured through GPC (in terms of polystyrene standards), the weight average molecular weight (Mw) was 6,699. Then, the polymer (16) was prepared as a propylene glycol monomethyl ether acetate solution having a solid content of 25 wt %, and the solution was stirred with a cation exchange resin and an anion exchange resin for 4 hours and then filtered to obtain a 21.92 wt % resin solution (16).

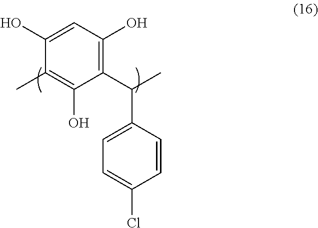

### Example 1

8.64 g of the resin solution obtained in Synthesis Example 1 was mixed with 0.17 g of propylene glycol monomethyl ether acetate containing 1% of a surfactant (trade name: Megaface [product name] R-40, fluorine-based surfactant, commercially available from DIC Corporation), 2.39 g of propylene glycol monomethyl ether, and 3.78 g of propylene glycol monomethyl ether acetate. Then, the mixture was filtered through a polytetrafluoroethylene microfilter having a pore size of 0.1 μm to prepare a solution of composition (1).

### Example 2

7.08 g of the resin solution obtained in Synthesis Example 1 was mixed with 1.47 g of a PGME solution containing 2 mass % of pyridinium p-toluenesulfonate, 0.29 g of TMOM-BP (crosslinking agent, commercially available from Honshu Chemical Industry Co., Ltd.), 0.14 g of propylene glycol monomethyl ether acetate containing 1% of a surfactant (trade name: Megaface [product name] R-40, fluorine-based surfactant, commercially available from DIC Corporation), 2.18 g of propylene glycol monomethyl ether, and 3.81 g of propylene glycol monomethyl ether acetate. Then, the mixture was filtered through a polytetrafluoroethylene microfilter having a pore size of 0.1 μm to prepare a solution of composition (2).

### Example 3

6.53 g of the resin solution obtained in Synthesis Example 2 was mixed with 0.23 g of propylene glycol monomethyl ether acetate containing 1% of a surfactant (trade name: Megaface [product name] R-40, fluorine-based surfactant, commercially available from DIC Corporation), 8.18 g of propylene glycol monomethyl ether, and 5.04 g of propylene glycol monomethyl ether acetate. Then, the mixture was filtered through a polytetrafluoroethylene microfilter having a pore size of 0.1 μm to prepare a solution of composition (3).

### Example 4

5.35 g of the resin solution obtained in Synthesis Example 2 was mixed with 1.96 g of propylene glycol monomethyl ether containing 2% of pyridinium p-hydroxybenzenesulfonate, 0.39 g of TMOM-BP (crosslinking agent, commercially available from Honshu Chemical Industry Co., Ltd.), 0.19 g of propylene glycol monomethyl ether acetate containing 1% of a surfactant (trade name: Megaface [product name] R-40, fluorine-based surfactant, commercially available from DIC Corporation), 7.00 g of propylene glycol monomethyl ether, and 5.08 g of propylene glycol monomethyl ether acetate. Then, the mixture was filtered through a polytetrafluoroethylene microfilter having a pore size of 0.1 μm to prepare a solution of composition (4).

### Example 5

5.27 g of the resin solution obtained in Synthesis Example 3 was mixed with 0.15 g of propylene glycol monomethyl ether acetate containing 1% of a surfactant (trade name: Megaface [product name] R-40, fluorine-based surfactant, commercially available from DIC Corporation), 6.60 of propylene glycol monomethyl ether acetate, and 2.97 g of cyclohexanone. Then, the mixture was filtered through a polytetrafluoroethylene microfilter having a pore size of 0.1 μm to prepare a solution of composition (5).

### Example 6

4.32 g of the resin solution obtained in Synthesis Example 3 was mixed with 1.22 g of propylene glycol monomethyl ether containing 2% of pyridinium p-hydroxybenzenesulfonate, 0.24 g of TMOM-BP (crosslinking agent, commercially available from Honshu Chemical Industry Co., Ltd.), 0.12 g of propylene glycol monomethyl ether acetate containing 1% of a surfactant (trade name: Megaface [product name] R-40, fluorine-based surfactant, commercially available from DIC Corporation), 0.14 g of propylene glycol monomethyl ether, 5.27 g of propylene glycol monomethyl ether acetate, and 3.65 g of cyclohexanone. Then, the mixture was filtered through a polytetrafluoroethylene microfilter having a pore size of 0.1 μm to prepare a solution of composition (6).

### Example 7

8.60 g of the resin solution obtained in Synthesis Example 4 was mixed with 0.23 g of propylene glycol monomethyl ether acetate containing 1% of a surfactant (trade name: Megaface [product name] R-40, fluorine-based surfactant, commercially available from DIC Corporation), 5.28 g of propylene glycol monomethyl ether, and 5.87 g of propylene glycol monomethyl ether acetate. Then, the mixture was filtered through a polytetrafluoroethylene microfilter having a pore size of 0.1 μm to prepare a solution of composition (7).

### Example 8

7.05 g of the resin solution obtained in Synthesis Example 4 was mixed with 1.96 g of propylene glycol monomethyl ether containing 2% of pyridinium p-hydroxybenzenesulfonate, 0.39 g of TMOM-BP (crosslinking agent, commercially available from Honshu Chemical Industry Co., Ltd.), 0.19 g of propylene glycol monomethyl ether acetate containing 1% of a surfactant (trade name: Megaface [product name] R-40, fluorine-based surfactant, commercially available from DIC Corporation), 3.35 g of propylene glycol monomethyl ether, and 7.03 g of propylene glycol monomethyl ether acetate. Then, the mixture was filtered through a polytetrafluoroethylene microfilter having a pore size of 0.1 μm to prepare a solution of composition (8).

### Example 9

9.42 g of the resin solution obtained in Synthesis Example 5 was mixed with 0.19 g of propylene glycol monomethyl ether acetate containing 1% of a surfactant (trade name: Megaface [product name] R-40, fluorine-based surfactant, commercially available from DIC Corporation), 5.40 g of propylene glycol monomethyl ether, and 4.97 g of propylene glycol monomethyl ether acetate. Then, the mixture was filtered through a polytetrafluoroethylene microfilter having a pore size of 0.1 μm to prepare a solution of composition (9).

### Example 10

7.73 g of the resin solution obtained in Synthesis Example 5 was mixed with 1.63 g of propylene glycol monomethyl ether containing 2% of pyridinium p-hydroxybenzenesulfonate, 0.32 g of TMOM-BP (crosslinking agent, commercially available from Honshu Chemical Industry Co., Ltd.), 0.16 g of propylene glycol monomethyl ether acetate containing 1% of a surfactant (trade name: Megaface [product name] R-40, fluorine-based surfactant, commercially available from DIC Corporation), 3.79 g of propylene glycol monomethyl ether, and 6.34 g of propylene glycol monomethyl ether acetate. Then, the mixture was filtered through a polytetrafluoroethylene microfilter having a pore size of 0.1 μm to prepare a solution of composition (10).

### Example 11

14.41 g of the resin solution obtained in Synthesis Example 6 was mixed with 0.29 g of propylene glycol monomethyl ether acetate containing 1% of a surfactant (trade name: Megaface [product name] R-40, fluorine-based surfactant, commercially available from DIC Corporation), 6.60 g of propylene glycol monomethyl ether, and 3.68 g of propylene glycol monomethyl ether acetate. Then, the mixture was filtered through a polytetrafluoroethylene microfilter having a pore size of 0.1 μm to prepare a solution of composition (11).

### Example 12

13.09 g of the resin solution obtained in Synthesis Example 7 was mixed with 0.29 g of propylene glycol monomethyl ether acetate containing 1% of a surfactant (trade name: Megaface [product name] R-40, fluorine-based surfactant, commercially available from DIC Corporation), 1.50 g of propylene glycol monomethyl ether, and 5.20 g of propylene glycol monomethyl ether acetate. Then, the mixture was filtered through a polytetrafluoroethylene microfilter having a pore size of 0.1 μm to prepare a solution of composition (12).

### Example 13

10.73 g of the resin solution obtained in Synthesis Example 7 was mixed with 1.63 g of propylene glycol monomethyl ether containing 2% of pyridinium p-hydroxybenzenesulfonate, 0.32 g of TMOM-BP (crosslinking agent, commercially available from Honshu Chemical Industry Co., Ltd.), 0.16 g of propylene glycol monomethyl ether acetate containing 1% of a surfactant (trade name: Megaface [product name] R-40, fluorine-based surfactant, commercially available from DIC Corporation), 1.89 g of propylene glycol monomethyl ether, and 5.23 g of propylene glycol monomethyl ether acetate. Then, the mixture was filtered through a polytetrafluoroethylene microfilter having a pore size of 0.1 μm to prepare a solution of composition (13).

### Example 14

7.08 g of the resin solution obtained in Synthesis Example 8 was mixed with 0.19 g of propylene glycol monomethyl ether acetate containing 1% of a surfactant (trade name: Megaface [product name] R-40, fluorine-based surfactant, commercially available from DIC Corporation), 3.71 g of propylene glycol monomethyl ether, and 9.00 g of cyclohexanone. Then, the mixture was filtered through a polytetrafluoroethylene microfilter having a pore size of 0.1 μm to prepare a solution of composition (14).

### Example 15

5.80 g of the resin solution obtained in Synthesis Example 8 was mixed with 1.63 g of propylene glycol monomethyl ether containing 2% of pyridinium p-hydroxybenzenesulfonate, 0.32 g of TMOM-BP (crosslinking agent, commercially available from Honshu Chemical Industry Co., Ltd.), 0.16 g of propylene glycol monomethyl ether acetate containing 1% of a surfactant (trade name: Megaface [product name] R-40, fluorine-based surfactant, commercially available from DIC Corporation), 0.19 g of propylene glycol monomethyl ether, 7.03 g of propylene glycol monomethyl ether acetate, and 4.83 g of cyclohexanone. Then, the mixture was filtered through a polytetrafluoroethylene microfilter having a pore size of 0.1 μm to prepare a solution of composition (15).

### Example 16

8.80 g of the resin solution obtained in Synthesis Example 9 was mixed with 0.24 g of propylene glycol monomethyl ether acetate containing 1% of a surfactant (trade name: Megaface [product name] R-40, fluorine-based surfactant, commercially available from DIC Corporation) and 10.95 g of propylene glycol monomethyl ether acetate. Then, the mixture was filtered through a polytetrafluoroethylene microfilter having a pore size of 0.1 μm to prepare a solution of composition (16).

### Example 17

7.22 g of the resin solution obtained in Synthesis Example 9 was mixed with 1.96 g of propylene glycol monomethyl ether containing 2% of pyridinium p-hydroxybenzenesulfonate, 0.39 g of TMOM-BP (crosslinking agent, commercially available from Honshu Chemical Industry Co., Ltd.), 0.19 g of propylene glycol monomethyl ether acetate containing 1% of a surfactant (trade name: Megaface [product name] R-40, fluorine-based surfactant, commercially available from DIC Corporation), 3.35 g of propylene glycol monomethyl ether, and 6.86 g of propylene glycol monomethyl ether acetate. Then, the mixture was filtered through a polytetrafluoroethylene microfilter having a pore size of 0.1 μm to prepare a solution of composition (17).

### Comparative Example 1

7.46 g of the resin solution obtained in Comparative Synthesis Example 1 was mixed with 0.23 g of propylene glycol monomethyl ether acetate containing 1% of a surfactant (trade name: Megaface [product name] R-40, fluorine-based surfactant, commercially available from DIC Corporation), 3.57 g of propylene glycol monomethyl ether, and 3.78 g of propylene glycol monomethyl ether acetate. Then, the mixture was filtered through a polytetrafluoroethylene microfilter having a pore size of 0.1 μm to prepare a solution of composition (18).

### Comparative Example 2

2.82 g of the resin solution obtained in Comparative Synthesis Example 2 was mixed with 0.06 g of propylene glycol monomethyl ether acetate containing 1% of a surfactant (trade name: Megaface [product name] R-40, fluorine-based surfactant, commercially available from DIC Corporation), 1.37 g of propylene glycol monomethyl ether, and 0.94 g of propylene glycol monomethyl ether acetate. Then, the mixture was filtered through a polytetrafluoroethylene microfilter having a pore size of 0.1 μm to prepare a solution of composition (19).

### Comparative Example 3

8.55 g of the resin solution obtained in Comparative Synthesis Example 3 was mixed with 0.23 g of propylene glycol monomethyl ether acetate containing 1% of a surfactant (trade name: Megaface [product name] R-40, fluorine-based surfactant, commercially available from DIC Corporation), 5.28 g of propylene glycol monomethyl ether, and 0.94 g of propylene glycol monomethyl ether acetate. Then, the mixture was filtered through a polytetrafluoroethylene microfilter having a pore size of 0.1 μm to prepare a solution of composition (20).

### Comparative Example 4

7.01 g of the resin solution obtained in Comparative Synthesis Example 3 was mixed with 1.96 g of propylene glycol monomethyl ether containing 2% of pyridinium p-hydroxybenzenesulfonate, 0.39 g of TMOM-BP (crosslinking agent, commercially available from Honshu Chemical Industry Co., Ltd.), 0.19 g of propylene glycol monomethyl ether acetate containing 1% of a surfactant (trade name: Megaface [product name] R-40, fluorine-based surfactant, commercially available from DIC Corporation), 3.35 g of propylene glycol monomethyl ether, and 7.07 g of propylene glycol monomethyl ether acetate. Then, the mixture was filtered through a polytetrafluoroethylene microfilter having a pore size of 0.1 μm to prepare a solution of composition (21).

### Comparative Example 5

7.45 g of the resin solution obtained in Comparative Synthesis Example 4 was mixed with 0.19 g of propylene glycol monomethyl ether acetate containing 1% of a surfactant (trade name: Megaface [product name] R-40, fluorine-based surfactant, commercially available from DIC Corporation), 3.34 g of propylene glycol monomethyl ether, and 9.00 g of propylene glycol monomethyl ether acetate. Then, the mixture was filtered through a polytetrafluoroethylene microfilter having a pore size of 0.1 μm to prepare a solution of composition (22).

### Comparative Example 6

6.11 g of the resin solution obtained in Comparative Synthesis Example 4 was mixed with 1.63 g of propylene glycol monomethyl ether containing 2% of pyridinium p-hydroxybenzenesulfonate, 0.32 g of TMOM-BP (crosslinking agent, commercially available from Honshu Chemical Industry Co., Ltd.), 0.16 g of propylene glycol monomethyl ether acetate containing 1% of a surfactant (trade name: Megaface [product name] R-40, fluorine-based surfactant, commercially available from DIC Corporation), 0.19 g of propylene glycol monomethyl ether, 7.03 g of propylene glycol monomethyl ether acetate, and 4.52 g of cyclohexanone. Then, the mixture was filtered through a polytetrafluoroethylene microfilter having a pore size of 0.1 μm to prepare a solution of composition (23).

### Comparative Example 7

6.11 g of the resin solution obtained in Comparative Synthesis Example 5 was mixed with 1.63 g of propylene glycol monomethyl ether containing 2% of pyridinium p-hydroxybenzenesulfonate, 0.32 g of TMOM-BP (crosslinking agent, commercially available from Honshu Chemical Industry Co., Ltd.), 0.16 g of propylene glycol monomethyl ether acetate containing 1% of a surfactant (trade name: Megaface [product name] R-40, fluorine-based surfactant, commercially available from DIC Corporation), 0.19 g of propylene glycol monomethyl ether, 7.03 g of propylene glycol monomethyl ether acetate, and 4.52 g of cyclohexanone. Then, the mixture was filtered through a polytetrafluoroethylene microfilter having a pore size of 0.1 μm to prepare a solution of composition (24).

### Comparative Example 8

10.56 g of the resin solution obtained in Comparative Synthesis Example 6 was mixed with 0.23 g of propylene glycol monomethyl ether acetate containing 1% of a surfactant (trade name: Megaface [product name] R-40, fluorine-based surfactant, commercially available from DIC Corporation), 5.28 g of propylene glycol monomethyl ether, and 3.91 g of propylene glycol monomethyl ether acetate. Then, the mixture was filtered through a polytetrafluoroethylene microfilter having a pore size of 0.1 μm to prepare a solution of composition (25).

### Comparative Example 9

10.93 g of the resin solution obtained in Comparative Synthesis Example 7 was mixed with 0.23 g of propylene glycol monomethyl ether acetate containing 1% of a surfactant (trade name: Megaface [product name] R-40, fluorine-based surfactant, commercially available from DIC Corporation), and 8.82 g of propylene glycol monomethyl ether acetate. Then, the mixture was filtered through a polytetrafluoroethylene microfilter having a pore size of 0.1 μm to prepare a solution of composition (26).

### (Test of Dissolving in Photoresist Solvent)

Each of the compositions prepared in Example 1 to Example 17, and Comparative Examples 1 to 9 was applied as a resist underlayer film-forming composition onto a silicon wafer using a spinner. Then, baking was performed on a hot plate at 350° C. under Air for 60 seconds, and baking was then performed at 450° C. under N₂ for 90 seconds to form a resist underlayer film (with a film thickness of about 0.21 μm). These resist underlayer films were immersed in a mixed solvent of PGME/PGMEA (a mass mixing ratio of 70/30), which are solvents used in a photoresist solution, it was confirmed that they were insoluble in the solvent, and the results are shown as “O” in the following Table 1.

TABLE 1

| | Dissolution test |
|---|---|
| Example 1 | ◯ |
| Example 2 | ◯ |
| Example 3 | ◯ |
| Example 4 | ◯ |
| Example 5 | ◯ |
| Example 6 | ◯ |
| Example 7 | ◯ |
| Example 8 | ◯ |
| Example 9 | ◯ |
| Example 10 | ◯ |
| Example 11 | ◯ |
| Example 12 | ◯ |
| Example 13 | ◯ |
| Example 14 | ◯ |
| Example 15 | ◯ |
| Example 16 | ◯ |
| Example 17 | ◯ |
| Comparative | ◯ |
| Example 1 | |
| Comparative | ◯ |
| Example 2 | |
| Comparative | ◯ |
| Example 3 | |
| Comparative | ◯ |
| Example 4 | |
| Comparative | ◯ |
| Example 5 | |
| Comparative | ◯ |
| Example 6 | |
| Comparative | ◯ |
| Example 7 | |
| Comparative | ◯ |
| Example 8 | |
| Comparative | ◯ |
| Example 9 | |

### (Hardness Test and Relative Dry Etching Rate Test)

Each of the compositions prepared in Example 1 to Example 17, and Comparative Example 1 to Comparative Example 9 was applied as a resist underlayer film-forming composition to a silicon wafer and a 200 nm resist underlayer film was then formed under baking conditions. The hardness of the cured resist film was evaluated using a TI-980 triboidentor (commercially available from Bruker Corporation). The results are shown in Table 2 and Table 3.

The compositions prepared in Example 1 to Example 17, and Comparative Example 1 to Comparative Example 9 were used as resist underlayer film-forming compositions, and resist underlayer films were formed on silicon wafers according to the same method as above. Then, the dry etching rate of these resist underlayer films was measured using RIE-10NR (commercially available from SAMCO Inc.) under conditions in which CF4 was used as an etching gas. The dry etching rate of each of the resist underlayer films when the dry etching rate of Comparative Example 1-1 was set to 1.00 was calculated. The results are shown in Table 2 and Table 3 as “relative dry etching rate.”

In Table 2 and Table 3, Air represents an air atmosphere, and N₂ represents a nitrogen atmosphere. In Table 2, the “rate of increase of the hardness at 450° C._N₂ relative to 350° C._Air” and the “rate of increase of the etch rate at 450° C._N₂ relative to 350° C._Air” are, for example, the rate of increase of the hardness of Example 1-2 relative to the hardness of Example 1-1 and the rate of increase of the relative dry etching rate of Example 1-2 relative to the relative dry etching rate of Example 1-1, respectively. In Table 3, the “rate of increase of the hardness at 450° C._N₂ relative to 350° C._Air” and the “rate of increase of the etch rate at 450° C._N₂ relative to 350° C. Air” are, for example, the rate of increase of the hardness of Comparative Example 1-2 relative to the hardness of Comparative Example 1-1, and the rate of increase of the relative dry etching rate of Comparative Example 1-2 relative to the relative dry etching rate of Comparative Example 1-1, respectively.

TABLE 2

| | | | | Rate of | Rate of |
|---|---|---|---|---|---|
| | | | | increase of | increase of |
| | | | Relative | hardness at | etch rate at |
| | | | dry | 450° C._N₂ | 450° C._N₂ |
| | | Hardness | etching | relative to | relative to |
| | Baking conditions | [GPa] | rate | 350° C._Air | 350° C._Air |
| Example 1-1 | 350° C./60 s_Air | 0.66 | 1.28 | 102% | 14% |
| Example 1-2 | 350° C./60 s_Air + | 1.33 | 1.10 | | |
| | 450° C./90 s_N₂ | | | | |
| Example 2-1 | 350° C./60 s_Air | 0.74 | 1.25 | 58% | 13% |
| Example 2-2 | 350° C./60 s_Air + | 1.17 | 1.09 | | |
| | 450° C./90 s_N₂ | | | | |
| Example 3-1 | 350° C./60 s_Air | 0.53 | 1.00 | 23% | 6% |
| Example 3-2 | 350° C./60 s_Air + | 0.65 | 0.94 | | |
| | 450° C./90 s_N₂ | | | | |
| Example 4-1 | 350° C./60 s_Air | 0.77 | 1.07 | 12% | 6% |
| Example 4-2 | 350° C./60 s_Air + | 0.86 | 1.00 | | |
| | 450° C./90 s_N₂ | | | | |
| Example 5-1 | 350° C./60 s_Air | 0.54 | 1.13 | 20% | 12% |
| Example 5-2 | 350° C./60 s_Air + | 0.65 | 0.99 | | |
| | 450° C./90 s_N₂ | | | | |
| Example 6-1 | 350° C./60 s_Air | 0.68 | 1.13 | 26% | 8% |
| Example 6-2 | 350° C./60 s_Air + | 0.86 | 1.04 | | |
| | 450° C./90 s_N₂ | | | | |
| Example 7-1 | 350° C./60 s_Air | 0.57 | 0.95 | 16% | 8% |
| Example 7-2 | 350° C./60 s_Air + | 0.66 | 0.88 | | |
| | 450° C./90 s_N₂ | | | | |
| Example 8-1 | 350° C./60 s_Air | 0.65 | 1.01 | 28% | 10% |
| Example 8-2 | 350° C./60 s_Air + | 0.83 | 0.92 | | |
| | 450° C./90 s_N₂ | | | | |
| Example 9-1 | 350° C./60 s_Air | 0.41 | 0.88 | 24% | 8% |
| Example 9-2 | 350° C./60 s_Air + | 0.51 | 0.81 | | |
| | 450° C./90 s_N₂ | | | | |
| Example 10-1 | 350° C./60 s_Air | 0.4 | 0.88 | 35% | 5% |
| Example 10-2 | 350° C./60 s_Air + | 0.54 | 0.84 | | |
| | 450° C./90 s_N₂ | | | | |
| Example 11-1 | 350° C./60 s_Air | 0.59 | 1.09 | 58% | 7% |
| Example 11-2 | 350° C./60 s_Air + | 0.93 | 1.01 | | |
| | 450° C./90 s_N₂ | | | | |
| Example 12-1 | 350° C./60 s_Air | 0.57 | 1.08 | 26% | 6% |
| Example 12-2 | 350° C./60 s_Air + | 0.72 | 1.01 | | |
| | 450° C./90 s_N₂ | | | | |
| Example 13-1 | 350° C./60 s_Air | 0.85 | 1.16 | | |
| Example 13-2 | 350° C./60 s_Air + | 0.99 | 1.04 | 16% | 10% |
| | 450° C./90 s_N₂ | | | | |
| Example 13-3 | 350° C./60 s_Air + | 1.21 | 0.88 | 42% | 24% |
| | 550° C./90 s_N₂ | | | | |
| Example 14-1 | 350° C./60 s_Air | 0.55 | 1.05 | 18% | 6% |
| Example 14-2 | 350° C./60 s_Air + | 0.65 | 0.99 | | |
| | 450° C./90 s_N₂ | | | | |
| Example 15-1 | 350° C./60 s_Air | 0.64 | 1.10 | 11% | 6% |
| Example 15-2 | 350° C./60 s_Air + | 0.71 | 1.04 | | |
| | 450° C./90 s_N₂ | | | | |
| Example 16-1 | 350° C./60 s_Air | 0.24 | 0.84 | 79% | 5% |
| Example 16-2 | 350° C./60 s_Air + | 0.43 | 0.80 | | |
| | 450° C./90 s_N₂ | | | | |
| Example 17-1 | 350° C./60 s_Air | 0.46 | 0.90 | 17% | 9% |
| Example 17-2 | 350° C./60 s_Air + | 0.54 | 0.82 | | |
| | 450° C./90 s_N₂ | | | | |

TABLE 3

| | | | | Rate of | Rate of |
|---|---|---|---|---|---|
| | | | | increase of | increase of |
| | | | Relative | hardness at | etch rate at |
| | | | dry | 450° C._N₂ | 450° C._N₂ |
| | | Hardness | etching | relative to | relative to |
| | Baking conditions | [GPa] | rate | 350° C._Air | 350° C._Air |
| Comparative | 350° C./60 s_Air | 0.44 | 1.00 | −5% | 8% |
| Example 1-1 | | | | | |
| Comparative | 350° C./60 s_Air + | 0.42 | 0.92 | | |
| Example 1-2 | 450° C./90 s_N₂ | | | | |
| Comparative | 350° C./60 s_Air | 0.39 | 0.83 | −18% | 4% |
| Example 2-1 | | | | | |
| Comparative | 350° C./60 s_Air + | 0.32 | 0.80 | | |
| Example 2-2 | 450° C./90 s_N₂ | | | | |
| Comparative | 350° C./60 s_Air | 0.45 | 0.85 | 4% | 6% |
| Example 3-1 | | | | | |
| Comparative | 350° C./60 s_Air + | 0.47 | 0.80 | | |
| Example 3-2 | 450° C./90 s_N₂ | | | | |
| Comparative | 350° C./60 s_Air | 0.67 | 0.83 | −4% | 5% |
| Example 4-1 | | | | | |
| Comparative | 350° C./60 s_Air + | 0.64 | 0.79 | | |
| Example 4-2 | 450° C./90 s_N₂ | | | | |
| Comparative | 350° C./60 s_Air | 0.46 | 0.98 | 2% | 4% |
| Example 5-1 | | | | | |
| Comparative | 350° C./60 s_Air + | 0.47 | 0.95 | | |
| Example 5-2 | 450° C./90 s_N₂ | | | | |
| Comparative | 350° C./60 s_Air | 0.52 | 1.05 | 4% | 9% |
| Example 6-1 | | | | | |
| Comparative | 350° C./60 s_Air + | 0.54 | 0.96 | | |
| Example 6-2 | 450° C./90 s_N₂ | | | | |
| Comparative | 350° C./60 s_Air | — | — | — | — |
| Example 7-1 | | | | | |
| Comparative | 350° C./60 s_Air + | — | — | | |
| Example 7-2 | 450° C./90 s_N₂ | | | | |
| Comparative | 350° C./60 s_Air | 0.38 | 0.89 | 8% | 7% |
| Example 8-1 | | | | | |
| Comparative | 350° C./60 s_Air + | 0.41 | 0.83 | | |
| Example 8-2 | 450° C./90 s_N₂ | | | | |
| Comparative | 350° C./60 s_Air | 0.48 | 1.22 | 0% | 7% |
| Example 9-1 | | | | | |
| Comparative | 350° C./60 s_Air + | 0.48 | 1.13 | | |
| Example 9-2 | 450° C./90 s_N₂ | | | | |

1. A method for improving hardness of a baked product, comprising
baking a composition including a compound containing one or more structures of the following Formula (1) at 400° C. to 600° C. under an inert gas atmosphere to increase hardness of an obtained baked product by 10% or more compared to hardness of a baked product at 350° C. under an air atmosphere:

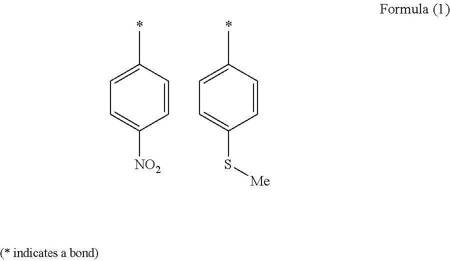

2. The method for improving hardness of a baked product according to claim 1,
wherein the compound contains a polymer structure having at least one repeating unit of the following Formula (2): 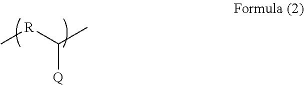
(wherein R is a divalent group having an aromatic ring, a condensed aromatic ring, or a condensed aromatic heterocycle, and Q is one of the structures of Formula (1)).

3. The method for improving hardness of a baked product according to claim 2,
wherein R is a divalent group in which hydrogen atoms on an aromatic ring having a structure of the following Formula (3), Formula (4), or Formula (5) are substituted: 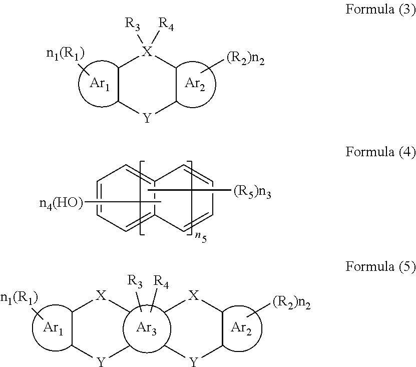
(in Formula (3), at least one of X and Y is present; X is a nitrogen atom or a carbon atom, Y is a single bond, a sulfur atom, or an oxygen atom; each of Ar₁ and Ar₂ is independently a benzene ring or a naphthalene ring which is arbitrarily substituted with R₁ or R₂, each of R₁ and R₂ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, or a combination thereof which arbitrarily contains an ether bond, a ketone bond, or an ester bond; each of n₁ and n₂ is an integer of 1 to 3 when Ar₁ and Ar₂ are benzene rings, and an integer of 1 to 5 when Ar₁ and Ar₂ are naphthalene rings; and each of R₃ and R₄ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, a phenyl group, a phenyl group substituted with a hydroxyl group, or a combination thereof which arbitrarily contains an ether bond, a ketone bond, or an ester bond; where, when X is a nitrogen atom, R₄ is absent; in Formula (4), R₅ is a C₁₋₃ alkyl group, n₃ is an integer of 0 to 4, n₄ is an integer of 1 to 4, and n₅ is any of 0, 1, and 2; and in Formula (5), Ar₁, Ar₂, R₁, R₂, R₃, R₄, n₁, and n₂ are the same as above, Ar₃ is a benzene ring or a naphthalene ring which is arbitrarily substituted with R₃ and R₄; and R₃ and R₄ are the same as above).

4. The method for improving hardness of a baked product according to claim 2,
wherein R is a divalent group in which hydrogen atoms on an aromatic ring having any one of the following structures are substituted:

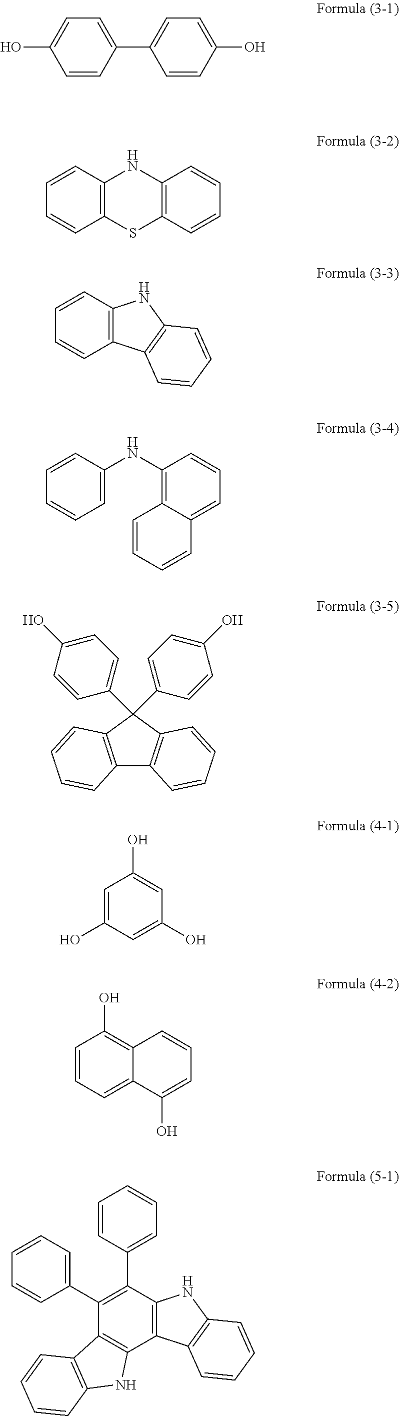

5. The method for improving hardness of a baked product according to claim 1, comprising a step of pre-baking the composition at 240° C. to 400° C. under an air atmosphere before baking the composition at 400° C. to 600° C. under an inert gas atmosphere.

6. A baked product of a composition including a compound containing one or more structures of the following Formula (1),
wherein hardness of the baked product is increased by 10% or more compared to hardness of a baked product baked at 350° C. under an air atmosphere.

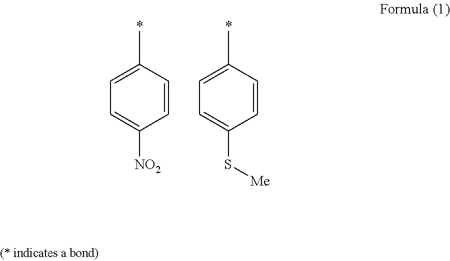

7. The baked product according to claim 6,
wherein the baked product is a baked product baked at 400° C. to 600° C. under an inert gas atmosphere.

8. The baked product according to claim 6,
wherein the baked product is a baked product baked at 240° C. to 400° C. under an air atmosphere and then at 400° C. to 600° C. under an inert gas atmosphere.

9. The baked product according to claim 6,
wherein the compound contains a polymer structure having at least one repeating unit of the following Formula (2): 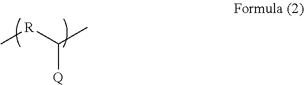
(wherein R is an organic group having an aromatic ring, a condensed aromatic ring, or a condensed aromatic heterocycle, and Q is one of the structures of Formula (1)).

10. The baked product according to claim 9,
wherein R is a divalent group in which hydrogen atoms on an aromatic ring having a structure of the following Formula (3), Formula (4), or Formula (5) are substituted: 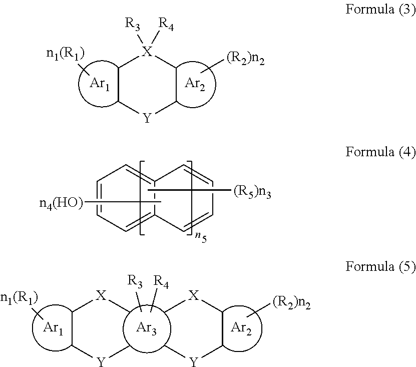
(in Formula (3), at least one of X and Y is present; X is a nitrogen atom or a carbon atom, Y is a single bond, a sulfur atom, or an oxygen atom; each of Ar₁ and Ar₂ is independently a benzene ring or a naphthalene ring which is arbitrarily substituted with R₁ or R₂, each of R₁ and R₂ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, or a combination thereof which arbitrarily contains an ether bond, a ketone bond, or an ester bond; each of n₁ and n₂ is an integer of 1 to 3 when Ar₁ and Ar₂ are benzene rings, and an integer of 1 to 5 when Ar₁ and Ar₂ are naphthalene rings; and each of R₃ and R₄ is a hydrogen atom, a halogen atom, a nitro group, an amino group, a hydroxyl group, a C₁₋₁₀ alkyl group, a C₂₋₁₀ alkenyl group, a C₂₋₁₀ alkynyl group, a phenyl group, a phenyl group substituted with a hydroxyl group, or a combination thereof which arbitrarily contains an ether bond, a ketone bond, or an ester bond; where, when X is a nitrogen atom, R₄ is absent; in Formula (4), R₅ is a C₁₋₃ alkyl group, n₃ is an integer of 0 to 4, n₄ is an integer of 1 to 4, and n₅ is any of 0, 1, and 2; and in Formula (5), Ar₁, Ar₂, R₁, R₂, R₃, R₄, n₁, and n₂ are the same as above, Ar₃ is a benzene ring or a naphthalene ring which is arbitrarily substituted with R₃ and R₄; and R₃ and R₄ are the same as above).

11. The baked product according to claim 9,
wherein R is a divalent group in which hydrogen atoms on an aromatic ring having any one of the following structures are substituted:

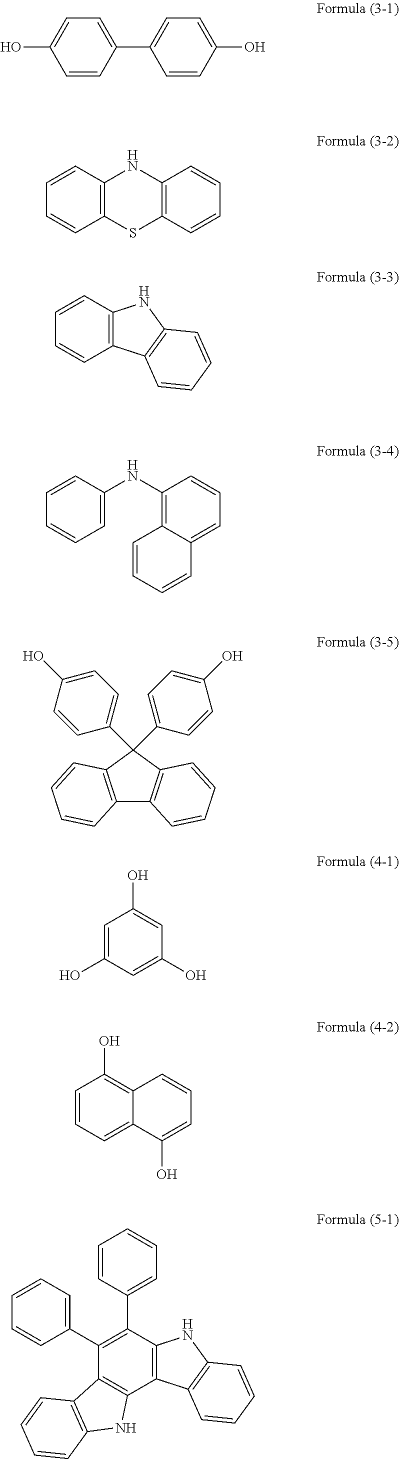

12. A resist underlayer film composed of the baked product according to claim 6.

13. A method of producing a resist underlayer film, comprising a step of forming the resist underlayer film according to claim 12 on a semiconductor substrate.

14. A method of producing a semiconductor device, comprising:
a step of forming the resist underlayer film according to claim 12 on a semiconductor substrate;
a step of forming a resist film thereon;
a step of forming a resist pattern by emitting light or an electron beam and developing;
a step of etching the underlayer film using the formed resist pattern; and
a step of processing the semiconductor substrate using the patterned underlayer film.

15. A method of producing a semiconductor device, comprising:
a step of forming the resist underlayer film according to claim 12 on a semiconductor substrate;
a step of forming a hard mask thereon;
a step of additionally forming a resist film thereon;
a step of forming a resist pattern by emitting light or an electron beam and developing;
a step of etching the hard mask using the formed resist pattern;
a step of etching the underlayer film using the patterned hard mask; and
a step of processing the semiconductor substrate using the patterned resist underlayer film.
